(19) United States
(12) Patent Application Publication
(10) Pub. No.: US 2024/0384065 A1
(43) Pub. Date: Nov. 21, 2024

(54) SILOXANE RESIN COMPOSITION FOR FORMING CURED FILM, CURED FILM, AND METHOD OF PRODUCING POLYSILOXANE

(71) Applicant: Toray Industries, Inc., Tokyo (JP)

(72) Inventors: Eisuke Iizuka, Otsu-shi, Shiga (JP); Mitsuhito Suwa, Otsu-shi, Shiga (JP); Manami Fujii, Otsu-shi, Shiga (JP); Masao Kamogawa, Otsu-shi, Shiga (JP)

(73) Assignee: Toray Industries, Inc., Tokyo (JP)

(21) Appl. No.: 18/691,307

(22) PCT Filed: Sep. 15, 2022
(86) PCT No.: PCT/JP2022/034553

§ 371 Date: Mar. 12, 2024

(30) Foreign Application Priority Data
Sep. 24, 2021 (JP) 2021-155227

(51) Int. Cl. C08K 5/3432; C08G 77/00; C08G 77/20; C08K 5/42; C09D 183/04; G03F 7/075

(52) U.S. Cl. CPC C08K 5/3432; C08G 77/20; C08K 5/42; C09D 183/04; G03F 7/0757; C08G 77/80

(57) ABSTRACT

A siloxane resin composition for forming a cured film includes: (a) a polysiloxane; (b) an organic salt; (c) a solvent; and (d) a photosensitizer, wherein a pH value in a 1.0% by mass aqueous solution of the (b) organic salt is 3.0 to 5.5, and the (d) photosensitizer is a photopolymerization initiator or a quinone diazide compound.

### TECHNICAL FIELD

This disclosure relates to a siloxane resin composition for forming a cured film, a cured film, and a method of producing a polysiloxane.

### BACKGROUND

Since a resin composition containing a polysiloxane is excellent in heat resistance, weather resistance, and transparency, the resin composition is widely used for applications such as optical lenses including microlens arrays for solid-state imaging elements, flattening films for TFTs intended for liquid crystal and organic EL displays, protective films and insulating films for touch panels, antireflection films, and optical filters.

In those applications, a cured film excellent in solvent resistance and the like is generally required in many instances, and to achieve required characteristics, it is necessary to increase the degree of curing of the film by promoting a reaction between polysiloxanes in the film (condensation reaction between silanol groups) at the time of forming the cured film.

To promote such a reaction, it is effective to contain a polysiloxane condensation catalyst such as an acid catalyst or a base catalyst in the resin composition. However, when those catalysts and a polysiloxane are simultaneously contained, a reaction between silanol groups proceeds with time, and problems such as thickening and gelation occur so that storage stability deteriorates. Therefore, a technique of using an acid generator or a base generator and accelerating the curing of a film by an acid or a base generated during an exposure step and/or a heating step has been reported (for example, Japanese Patent Laid-open Publication No. 2004-107562 and Japanese Patent Laid-open Publication No. 2006-154037).

The polysiloxane industrially used as described above is often synthesized by a sol-gel method using an alkoxysilane compound as a raw material using a hydrolysis reaction and a polycondensation reaction. In general, in the sol-gel method, hydrolysis and condensation reaction are promoted by using an acid or base catalyst, but when these catalysts remain in the polysiloxane solution after the reaction, problems such as thickening and gelation with time as described above occur. Therefore, in practice, a catalyst removal step (or neutralization reaction) is often required after the reaction. However, the introduction of those steps not only increases the cost, but also causes a decrease in yield, an increase in impurities and the like.

To obtain a polysiloxane having excellent storage stability without removing a catalyst, Japanese Patent Laid-open Publication No. H7-292108 reports a method using a fluoride salt which is a neutral compound as a catalyst.

International Publication No. 2016/098596 proposes a method of synthesizing using a neutral salt as a catalyst.

However, in the techniques of Japanese Patent Laid-open Publication No. 2004-107562 and Japanese Patent Laid-open Publication No. 2006-154037, an effective acid generator and base generator are generally expensive. When there is a metal wiring on the base, there is also a problem in that wiring corrosion occurs.

In the technique of Japanese Patent Laid-open Publication No. H7-292108, it is known that many of fluoride salts produce highly toxic hydrofluoric acid in an acidic aqueous solution, and there has been concern about safety, substrate corrosion and the like.

In the technique of International Publication No. 2016/098596, magnesium chloride, sodium chloride and the like are mentioned as suitable examples of the catalyst of the neutral salt, but when the neutral salt is used in semiconductor applications, there is a concern that alkali metal impurities derived from the catalyst may cause problems. Since these neutral salt catalysts are salts of a strong acid and a strong base, the pH of the aqueous solution is about 7, and there is a concern that the hydrolysis of the alkoxysilane compound hardly proceeds and the subsequent polycondensation reaction also hardly proceeds.

It could therefore be helpful to relatively inexpensively provide a siloxane resin composition for forming a cured film, the siloxane resin composition having exceptional storage stability and being capable of yielding a cured film that has exceptional solvent resistance as well as to produce a polysiloxane having excellent storage stability even without a catalyst removal step.

### SUMMARY

We thus provide:
[1] A resin composition for forming a cured film, the resin composition containing:
(a) a polysiloxane;
(b) an organic salt;
(c) a solvent; and
(d) a photosensitizer,
wherein a pH value in a 1.0% by mass aqueous solution of the (b) organic salt is 3.0 to 5.5, and the (d) photosensitizer is a photopolymerization initiator or a quinone diazide compound.
[2] The siloxane resin composition for forming a cured film according to [1], wherein a content of the (b) organic salt is 0.01 to 5.00 parts by mass based on 100 parts by mass of the (a) polysiloxane.
[3] The siloxane resin composition for forming a cured film according to [1] or [2], wherein the (b) organic salt is an organic salt composed of an organic acid having a structure represented by any one of general formulae (1) to (3) and an amine.
[4] The siloxane resin composition for forming a cured film according to [3], wherein the amine is a heterocyclic amine or an aromatic amine.
[5] The siloxane resin composition for forming a cured film according to [3] or [4], wherein the organic acid having a structure represented by any one of general formulae (1) to (3) is an organic acid selected from the group consisting of methanesulfonic acid, ethanesulfonic acid, propanesulfonic acid, benzenesulfonic acid, p-toluenesulfonic acid, xylenesulfonic acid, trifluoromethanesulfonic acid, trifluoroethanesulfonic acid, trifluoropropanesulfonic acid, and trifluoroacetic acid.
[6] The siloxane resin composition for forming a cured film according to [4], wherein the heterocyclic amine or the aromatic amine is an amine selected from the group consisting of pyridine, 2,4-dimethylpyridine, 2,6-dimethylpyridine, 3,5-dimethylpyridine, 2,4,6-trimethylpyridine, and aniline.
[7] The siloxane resin composition for forming a cured film according to [1], wherein the (d) photosensitizer is a photopolymerization initiator, and the siloxane resin composition further includes a photopolymerizable compound.
[8] The siloxane resin composition for forming a cured film according to any one of [1] to [7], wherein the (a) polysiloxane has an aromatic group and/or a substituted aromatic group in a side chain group, and a content of each of benzene, toluene, xylene, aniline, styrene, and naphthalene in the resin composition is less than 1 ppm.
[9] The siloxane resin composition for forming a cured film according to any one of [1] to [8], wherein the cured film is a permanent film.
[10] A cured film obtained by curing the resin composition for forming a cured film according to any one of [1] to [9].
[11] A cured film wherein an atomicity ratio of N to Si as measured by a scanning electron microscope (SEM-EDX) is 0.005 or more and 0.200 or less, and an atomicity ratio of at least one atom selected from S, P, and F to Si is 0.005 or more and 0.200 or less.
[12] The cured film according to [10], wherein an atomicity ratio of N to Si as measured by a scanning electron microscope (SEM-EDX) is 0.005 or more and 0.200 or less, and an atomicity ratio of at least one atom selected from S, P, and F to Si is 0.005 or more and 0.200 or less.
[13] A method of producing a polysiloxane, including producing a polysiloxane using an alkoxysilane as a raw material and using an organic salt as a catalyst for hydrolysis and/or thermal condensation, wherein a pH value in a 1.0% by mass aqueous solution of the organic salt is 3.0 to 5.5.

We provide a siloxane resin composition for forming a cured film, the siloxane resin composition having exceptional storage stability and being capable of yielding a cured film that has exceptional solvent resistance. We also provide a cured film having exceptional solvent resistance. We further provide a method of producing a polysiloxane having excellent storage stability even without a catalyst removal step.

### DETAILED DESCRIPTION

Hereinafter, preferred examples of a siloxane resin composition for forming a cured film, a cured film, and a method of producing a polysiloxane will be specifically described. However, this disclosure is not limited to the following examples, and various modifications can be made depending on purposes and applications.

The resin composition for forming a cured film contains (a) a polysiloxane, (b) an organic salt, and (c) a solvent.

### (a) Polysiloxane

The (a) polysiloxane is a hydrolysis/dehydration condensate of an alkoxysilane compound. The (a) polysiloxane preferably includes at least a repeating unit represented by general formula (4) and/or a repeating unit represented by general formula (5). When a thick film having a film thickness of 10 μm or more is formed, it is preferable to include a repeating unit derived from a bifunctional alkoxysilane compound represented by general formula (4). By including the repeating unit derived from a bifunctional alkoxysilane compound represented by general formula (4), excessive thermal polymerization (condensation) of the polysiloxane by heating can be suppressed, and the crack resistance of the cured film can be improved. By including a repeating unit derived from a trifunctional alkoxysilane compound represented by general formula (5), the crosslinking density of the polysiloxane increases after film formation, and the degree of curing of the cured film can be improved.

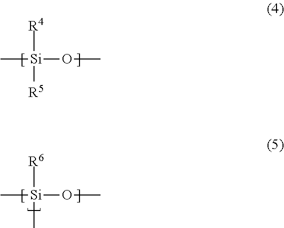

In general formula (4), R⁴ and R⁵ may be the same or different from each other, and each represent a monovalent organic group having 1 to 20 carbon atoms. R⁴ and R⁵ may be partially substituted with a radical-polymerizable group. In this example, in a cured product of the resin composition, the radical-polymerizable group may be radically polymerized. Examples of the radical-polymerizable group include a vinyl group, a (meth)acrylic group, and a styryl group. The polysiloxane may contain two or more kinds of repeating units represented by general formula (4) having different R⁴ and R⁵.

In general formula (5), R⁶ represents a monovalent organic group having 1 to 20 carbon atoms. R⁶ may be partially substituted with a radical-polymerizable group. In this example, in a cured product of the resin composition, the radical-polymerizable group may be radically polymerized. Examples of the radical-polymerizable group include a vinyl group, a (meth)acrylic group, and a styryl group. The polysiloxane may contain two or more kinds of repeating units represented by general formula (5) having different R⁶.

The repeating units represented by general formulae (4) and (5) are respectively derived from alkoxysilane compounds represented by general formulae (6) and (7). That is, the polysiloxane including the repeating units represented by general formulae (4) and (5) can be obtained by hydrolyzing and polycondensing an alkoxysilane compound including alkoxysilane compounds represented by general formulae (6) and (7). Still another alkoxysilane compound may be used.

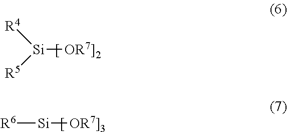

In general formulae (6) and (7), R⁴ to R⁶ represent the same groups as R⁴ to R⁶ in general formulae (4) and (5), respectively. R⁷ may be the same or different and represents hydrogen or a monovalent organic group having 1 to 20 carbon atoms and is preferably hydrogen or an alkyl group having 1 to 6 carbon atoms.

Examples of the alkoxysilane compound represented by general formula (6) include dimethyldimethoxysilane, dimethyldiethoxysilane, ethylmethyldimethoxysilane, ethylmethyldiethoxysilane, methylpropyldimethoxysilane, methylpropyldiethoxysilane, diphenyldimethoxysilane, diphenyldiethoxysilane, methylphenyldimethoxysilane, methylphenyldiethoxysilane, cyclohexylmethyldimethoxysilane, cyclohexylmethyldiethoxysilane, dicyclopentyldimethoxysilane, dicyclopentyldiethoxysilane, vinylmethyldimethoxysilane, vinylmethyldiethoxysilane, allylmethyldimethoxysilane, allylmethyldiethoxysilane, styrylmethyldimethoxysilane, styrylmethyldiethoxysilane, γ-methacryloylpropylmethyldimethoxysilane, γ-methacryloylpropylmethyldiethoxysilane, γ-acryloylpropylmethyldimethoxysilane, γ-acryloylpropylmethyldiethoxysilane, 3-glycidoxypropylmethyldimethoxysilane, 3-glycidoxypropylmethyldiethoxysilane, 2-(3,4-epoxycyclohexyl)ethylmethyldimethoxysilane, epoxycyclohexyl)ethylethyldimethoxysilane, methylphenyldimethoxysilane, methylphenyldiethoxysilane, 3-dimethylmethoxysilylpropylsuccinic anhydride, 3-dimethylethoxysilylpropylsuccinic anhydride, 3-dimethylmethoxysilylpropionic acid, 3-2-(3,4-dimethylethoxysilylpropionic acid, 3-dimethylmethoxysilylpropylcyclohexyldicarboxylic anhydride, 3-dimethylethoxysilylethoxysilylpropylcyclohexyldicarboxylic anhydride, 5-dimethylmethoxysilylvaleric acid, 5-dimethylethoxysilylvaleric acid, 3-dimethylmethoxysilylpropylphthalic anhydride, 3-dimethylethoxysilylpropylphthalic anhydride, 3-dimethylmethoxysilylpropylphthalic anhydride, 3-dimethylethoxysilylpropylphthalic anhydride, 4-dimethylmethoxysilylbutyric acid, 4-dimethylethoxysilylbutyric acid, bis(trifluoromethyl)dimethoxysilane, bis(trifluoropropyl)dimethoxysilane, bis(trifluoropropyl) diethoxysilane, trifluoropropylmethyldimethoxysilane, trifluoropropylmethyldiethoxysilane, trifluoropropylethyldimethoxysilane, trifluoropropylethyldiethoxysilane, heptadecafluorodecylmethyldimethoxysilane, and diphenylsilanediol. Two or more of these compounds may be used in combination.

Examples of the alkoxysilane compound represented by general formula (7) include trifunctional alkoxysilane compounds such as methyltrimethoxysilane, methyltriethoxysilane, ethyltrimethoxysilane, ethyltriethoxysilane, propyltrimethoxysilane, propyltriethoxysilane, isobutyltrimethoxysilane, isobutyltriethoxysilane, cyclohexyltrimethoxysilane, cyclohexyltriethoxysilane, 3-isocyanatopropyltrimethoxysilane, 3-isocyanatopropyltriethoxysilane, 3-aminopropyltrimethoxysilane, 3-aminopropyltriethoxysilane, 3-ureidopropyltrimethoxysilane, and 3-ureidopropyltriethoxysilane; epoxy group or oxetane group-containing alkoxysilane compounds such as 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, 3-ethyl-3-{[3-(trimethoxysilyl) propoxy]methyl}oxetane, and 3-ethyl-3-{[3-(triethoxysilyl) propoxy]methyl}oxetane; aromatic ring-containing alkoxysilane compounds such as phenyltrimethoxysilane, phenyltriethoxysilane, 1-naphthyltrimethoxysilane, 2-naphthyltrimethoxysilane, 2-naphthyltrimethoxysilane, 2-naphthyltrimethoxysilane, tolyltrimethoxysilane, tolyltriethoxysilane, 1-phenylethyltrimethoxysilane, 1-phenylethyltriethoxysilane, 2-phenylethyltrimethoxysilane, 2-phenylethyltriethoxysilane, 3-trimethoxysilylpropylphthalic anhydride, and 3-triethoxysilylpropylphthalic anhydride; radical-polymerizable group-containing alkoxysilane compounds such as styryltrimethoxysilane, styryltriethoxysilane, vinyltrimethoxysilane, vinyltriethoxysilane, allyltrimethoxysilane, allyltriethoxysilane, γ-acryloylpropyltrimethoxysilane, γ-acryloylpropyltriethoxysilane, γ-methacryloylpropyltrimethoxysilane, and γ-methacryloylpropyltriethoxysilane; carboxyl group-containing alkoxysilane compounds such as 3-trimethoxysilylpropionic acid, 3-triethoxysilylpropionic acid, 4-trimethoxysilylbutyric acid, 4-triethoxysilylbutyric acid, 5-trimethoxysilylvaleric acid, 5-triethoxysilylvaleric acid, 3-trimethoxysilylpropylsuccinic anhydride, 3-triethoxysilylpropylsuccinic anhydride, 3-trimethoxysilylpropylcyclohexyldicarboxylic anhydride, 3-triethoxysilylpropylcyclohexyldicarboxylic anhydride, 3-trimethoxysilylpropylphthalic anhydride, and 3-triethoxysilylpropylphthalic anhydride; and fluorine group-containing alkoxysilane compounds such as trifluoropropyltrimethoxysilane, trifluoropropyltriethoxysilane, perfluoropentyltrimethoxysilane, perfluoropentyltriethoxysilane, tridecafluorooctyltrimethoxysilane, tridecafluorooctyltriethoxysilane, tridecafluorooctyltripropoxysilane, tridecafluorooctyltriisopropoxysilane, heptadecafluorodecyltrimethoxysilane, and heptadecafluorodecyltriethoxysilane. Two or more of these compounds may be used in combination.

When the siloxane resin composition for forming a cured film has photocurability, it is preferable to contain at least one radical-polymerizable group-containing alkoxysilane compound as the alkoxysilane compound represented by general formula (6) and/or (7). When the siloxane resin composition for forming a cured film has negative photosensitivity, it is preferable to contain at least one radical-polymerizable group-containing alkoxysilane compound and at least one carboxyl group-containing alkoxysilane compound as the alkoxysilane compound represented by general formula (6) and/or (7). By containing the radical-polymerizable group-containing alkoxysilane compound, the crosslinking reaction proceeds by the radical generated in the exposed portion, and the degree of curing of the exposed portion can be increased. By containing the carboxyl group-containing alkoxysilane compound, the solubility of the unexposed portion is improved, and the resolution can be improved during pattern processing.

When the siloxane resin composition for forming a cured film has positive photosensitivity, it is preferable to contain at least an aromatic group-containing alkoxysilane compound as the alkoxysilane compound represented by general formula (6) and/or (7). By containing the aromatic group-containing alkoxysilane compound, the compatibility between the (a) polysiloxane and the photosensitizer can be enhanced.

Examples of other alkoxysilane compounds include tetrafunctional alkoxysilane compounds such as tetramethoxysilane, tetraethoxysilane, and Silicate 51 (tetraethoxysilane oligomer); and monofunctional alkoxysilane compounds such as trimethylmethoxysilane, triphenylmethoxysilane, trimethylsilanol, and triphenylsilanol. Two or more of these compounds may be used in combination.

The mass average molecular weight (Mw) of the (a) polysiloxane is preferably 1,000 or more, more preferably 2,000 or more from the viewpoint of the coating properties. On the other hand, the Mw of the polysiloxane is preferably 200,000 or less, more preferably 150,000 or less from the viewpoint of developability. Herein, the “Mw” of the polysiloxane refers to a polystyrene equivalent value measured by gel permeation chromatography (GPC).

The (a) polysiloxane can be obtained by hydrolyzing the above-mentioned alkoxysilane compound and then subjecting the hydrolysate to a dehydration condensation reaction.

Various conditions for the hydrolysis can be set in consideration of the reaction scale, the size and shape of the reaction container and the like according to physical properties suited for intended uses. Examples of the various conditions include an acid concentration, a reaction temperature, and a reaction time.

To promote the hydrolysis reaction and the dehydration condensation reaction, it is preferable to add a catalyst. As the catalyst, acids such as hydrochloric acid, acetic acid, formic acid, nitric acid, oxalic acid, hydrochloric acid, sulfuric acid, phosphoric acid, polyphosphoric acid, polycarboxylic acid, and anhydrides thereof, bases such as monoethanolamine, diethanolamine, triethanolamine, 3,3-dimethylbutylamine, methylpentylamine, n-butylethylamine, dibutylamine, n-butylamine, pentylamine, isopentylamine, cyclopentylamine, hexylamine, cyclohexylamine, dimethylhexylamine, N,N-dimethylbutylamine, N,N-dimethylhexadecylamine, and N,N-dimethyl-n-octylamine, and organic salts such as methanesulfonic acid pyridine salt, ethanesulfonic acid pyridine salt, propanesulfonic acid pyridine salt, benzenesulfonic acid pyridine salt, p-toluenesulfonic acid pyridine salt, xylene sulfonic acid pyridine salt, trifluoromethanesulfonic acid pyridine salt, trifluoroethanesulfonic acid pyridine salt, trifluoropropanesulfonic acid pyridine salt, trifluoroacetic acid pyridine salt, p-toluenesulfonic acid 2,4,6-trimethylpyridine salt, p-toluenesulfonic acid aniline salt, tetramethylammonium p-toluenesulfonate, tetraethylammonium p-toluenesulfonate, tetramethylammonium hydroxide, and tetraethylammonium hydroxide are used.

Among them, an organic salt having a pH value in a 1.0% by mass aqueous solution of 3.0 to 5.5 is preferably used. That is, a method of producing a polysiloxane is a method of producing a polysiloxane using an alkoxysilane compound as a raw material and using an organic salt as a catalyst for hydrolysis and/or thermal condensation, in which a pH value in a 1.0% by mass aqueous solution of the organic salt is 3.0 to 5.5.

Examples of the organic salt having a pH value in a 1.0% by mass aqueous solution of 3.0 to 5.5 include benzenesulfonic acid pyridine salt, methanesulfonic acid pyridine salt, p-toluenesulfonic acid pyridine salt, xylene sulfonic acid pyridine salt, trifluoromethanesulfonic acid pyridine salt, trifluoroethanesulfonic acid pyridine salt, trifluoropropanesulfonic acid pyridine salt, trifluoroacetic acid pyridine salt, p-toluenesulfonic acid 2,4,6-trimethylpyridine salt, and p-toluenesulfonic acid aniline salt. By using the organic salt having a pH value in a 1.0% by mass aqueous solution of 3.0 to 5.5, a polysiloxane having excellent storage stability can be produced even without a catalyst removal or neutralization step described below. The pH value in the 1.0% by mass aqueous solution of the organic salt is preferably 3.0 to 5.0, more preferably 3.0 to 4.5.

When a catalyst is used in the hydrolysis reaction and the dehydration condensation reaction, the addition amount of the catalyst is preferably 0.05 parts by mass or more, more preferably 0.1 parts by mass or more, based on 100 parts by mass of the total alkoxysilane compound used in the reaction, from the viewpoint of more rapidly progressing the reaction. On the other hand, from the viewpoint of appropriately adjusting the progress of the reaction, the addition amount of the catalyst is preferably 5.00 parts by mass or less, more preferably 3.00 parts by mass or less, based on 100 parts by mass of the total alkoxysilane compound. The total amount of alkoxysilane compound refers to an amount including all of an alkoxysilane compound, a hydrolysate thereof, and a condensate thereof. The same applies hereinafter.

The hydrolysis reaction and the dehydration condensation reaction are preferably performed in a solvent. The solvent can be appropriately selected in consideration of the stability, wettability, volatility and the like of the resin composition. When a solvent is formed through the hydrolysis reaction, the hydrolyzation can be carried out without a solvent. When the solvent is used in the resin composition, after completion of the hydrolysis reaction, it is also preferable to further add a solvent to adjust the concentration to be appropriate for the resin composition. It is also possible to distill and remove the whole amount or part of the produced alcohol and the like by heating and/or reducing the pressure after hydrolysis and then add a suitable solvent.

When a solvent is used in the hydrolysis reaction, the addition amount of the solvent is preferably 20 parts by mass or more, more preferably 40 parts by mass or more, based on 100 parts by mass of the total alkoxysilane compound, from the viewpoint of suppressing generation of a gel due to overreaction. On the other hand, from the viewpoint of more rapidly progressing the hydrolysis, the addition amount of the solvent is preferably 500 parts by mass or less, more preferably 200 parts by mass or less, based on 100 parts by mass of the total alkoxysilane compound.

The water used for the hydrolysis reaction is preferably ion-exchanged water. The amount of water can be arbitrarily set but is preferably 1.0 to 4.0 mol with respect to 1 mol of the total alkoxysilane compound.

Examples of the method of the dehydration condensation reaction include a method in which a silanol compound solution obtained by the hydrolysis reaction of the alkoxysilane compound is heated as it is. The heating temperature is preferably not lower than 50° C. and not higher than the boiling point of the solvent, and the heating time is preferably 1 to 100 hours. After the dehydration condensation reaction, it is also possible, depending on the purpose, to distill off an appropriate amount of products such as alcohols under heating and/or reduced pressure and then add a suitable solvent.

From the viewpoint of the storage stability of the resin composition, a catalyst removal or neutralization step may be performed as necessary. As the method of removing the catalyst, a process by water washing or with ion exchange resin is preferable from the viewpoint of ease of operation and removal characteristic. Washing with water is a method in which a polysiloxane solution is diluted with a suitable hydrophobic solvent, the resulting solution is washed with water several times, and the obtained organic layer is then concentrated with an evaporator or the like. The process with ion exchange resin refers to a method in which a polysiloxane solution is brought into contact with an appropriate ion exchange resin.

### (b) Organic Salt

The (b) organic salt is an organic salt compound composed of an acid and a base. The (b) organic salt acts as a condensation catalyst that promotes a condensation reaction of a silanol group remaining in the polysiloxane. When the (a) polysiloxane and the (b) organic salt are contained in the resin composition, the reaction between silanol groups in the polysiloxane is accelerated to increase the crosslinking density in the film so that the degree of curing of the cured film can be improved to improve the solvent resistance of the film.

Japanese Patent Laid-open Publication No. 2006-106311 discloses an example in which p-toluenesulfonic acid pyridine salt as an organic salt is used in a resist composition, but this is added for the purpose of suppressing the diffusion rate when the acid generated from the photoacid generator is diffused into the resist film, and the role of the (b) organic salt in the siloxane resin composition for forming a cured film used for forming a permanent film is clearly different.

Examples of the method of introducing the (b) organic salt into the resin composition include a method in which the (b) organic salt is used as a catalyst in the step of producing the (a) polysiloxane as described above and a polysiloxane solution obtained without performing the catalyst removal step is used, and a method in which the (b) organic salt is added to the (a) polysiloxane after removing the catalyst. From the viewpoint of process simplicity, the former method is preferable.

In the siloxane resin composition for forming a cured film, the (b) organic salt has a pH value in a 1.0% by mass aqueous solution of 3.0 to 5.5. By setting the pH value in this range, both the storage stability of the resin composition and the improvement in the degree of curing of the film can be achieved. Examples of the organic salt having a pH value in a 1.0% by mass aqueous solution of 3.0 to 5.5 include the organic salts described above as suitable catalysts. The pH value in the 1.0% by mass aqueous solution of the (b) organic salt is preferably 3.0 to 5.0, more preferably 3.0 to 4.5.

The content of the (b) organic salt in the resin composition for forming a cured film is preferably 0.01 parts by mass or more, more preferably 0.05 parts by mass or more, still more preferably 0.1 parts by mass or more, based on 100 parts by mass of the (a) polysiloxane, from the viewpoint of improving the degree of curing of the film. On the other hand, the content of the (b) organic salt in the resin composition for forming a cured film is preferably 5.00 parts by mass or less, more preferably 3.00 parts by mass or less, based on 100 parts by mass of the (a) polysiloxane, from the viewpoint of improving the storage stability and suppressing yellowing of the film.

The (b) organic salt is preferably a salt composed of a strong acid and a weak base to set the pH value in 1.0% by mass aqueous solution to the above preferable range. Therefore, the (b) organic salt is preferably an organic salt composed of an organic acid having a structure represented by any one of general formulae (1) to (3) and an amine.

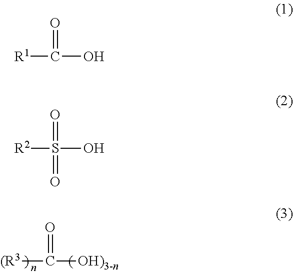

In general formulae (1) and (2), R¹ to R² each independently represent a monovalent organic group having 1 to 30 carbon atoms or a divalent organic group having 1 to 30 carbon atoms. Examples of the monovalent organic group include a substituted or unsubstituted linear or branched alkyl group, a substituted or unsubstituted cyclic alkyl group, a substituted or unsubstituted aryl group, and a perfluoroalkyl group, and examples of the divalent organic group include a substituted or unsubstituted alkylene group, a substituted or unsubstituted alkenylene group, and a substituted or unsubstituted phenylene group.

In general formula (3), n represents 0, 1, or 2. When n is 1, R³ in general formula (3) represents a monovalent organic group having 1 to 30 carbon atoms or a divalent organic group having 1 to 30 carbon atoms. When n is 2, R³ in general formula (3) may be the same or different and represents hydrogen, a monovalent organic group having 1 to 30 carbon atoms, or a divalent organic group having 1 to 30 carbon atoms.

Examples of the organic acid represented by general formula (1) include formic acid, acetic acid, propionic acid, butyric acid, valeric acid, caproic acid, enanthic acid, caprylic acid, pelargonic acid, capric acid, lauric acid, myristic acid, palmitic acid, margaric acid, stearic acid, trifluoroacetic acid, benzoic acid, phthalic acid, terephthalic acid, lactic acid, malic acid, tartaric acid, oxalic acid, malonic acid, succinic acid, maleic acid, fumaric acid, and adipic acid.

Examples of the organic acid represented by general formula (2) include methanesulfonic acid, ethanesulfonic acid, propanesulfonic acid, benzenesulfonic acid, p-toluenesulfonic acid, m-toluenesulfonic acid, o-toluenesulfonic acid, xylenesulfonic acid, 10-camphor sulfonic acid, magic acid, taurine, trifluoromethanesulfonic acid, trifluoroethanesulfonic acid, and trifluoropropanesulfonic acid.

Examples of the organic acid represented by general formula (3) include phosphoric acid, methylphosphonic acid, ethylphosphonic acid, propylphosphonic acid, butylphosphonic acid, pentylphosphonic acid, hexylphosphonic acid, cyclohexylphosphonic acid, heptylphosphonic acid, octylphosphonic acid, nonylphosphonic acid, decylphosphonic acid, icosylphosphonic acid, phenylphosphonic acid, vinylphosphonic acid, phenylphosphinic acid, tolylphosphonic acid, diethyl phosphate, dipropyl phosphate, dibutyl phosphate, dihexyl phosphate, and diphenyl phosphate.

Among them, from the viewpoint of ease of salt formation and availability, methanesulfonic acid, ethanesulfonic acid, propanesulfonic acid, benzenesulfonic acid, p-toluenesulfonic acid, xylenesulfonic acid, trifluoromethanesulfonic acid, trifluoroethanesulfonic acid, trifluoropropanesulfonic acid, or trifluoroacetic acid is preferable.

The structure of the amine is not particularly limited, but is preferably a weakly basic amine compound as described above. The amine is preferably a heterocyclic amine or an aromatic amine.

Examples of the heterocyclic amine include pyrrole, oxazole, isoxazole, thiazole, imidazole, pyrazole, 1,2,3-thiadiazole, pyridine, piperidine, pyridazine, pyrimidine, pyrazine, quinoline, isoquinoline, purine, pteridine, 2,4-dimethylpyridine, 2,6-dimethylpyridine, 3,5-dimethylpyridine, and 2,4,6-trimethylpyridine.

Examples of the aromatic amine include aniline, o-toluidine, 2,4,6-trimethylaniline, anisidine, and 3-(trifluoromethyl) aniline.

Among them, from the viewpoint of ease of salt formation and availability, pyridine, 2,4-dimethylpyridine, 2,6-dimethylpyridine, 3,5-dimethylpyridine, 2,4,6-trimethylpyridine, or aniline is preferable.

The (b) organic salt is preferably an organic salt including the preferred organic acid and the preferred amine described above. Among them, from the viewpoint of ease of salt formation and availability, methanesulfonic acid pyridine salt, ethanesulfonic acid pyridine salt, propanesulfonic acid pyridine salt, benzenesulfonic acid pyridine salt, p-toluenesulfonic acid pyridine salt, trifluoromethanesulfonic acid pyridine salt, trifluoropropanesulfonic acid pyridine salt, trifluoroacetic acid pyridine salt, xylene sulfonic acid pyridine salt, p-toluenesulfonic acid, and 2,4,6-trimethylpyridine salt are preferable. Among them, from the viewpoint of reducing the coloring of the cured film, methanesulfonic acid pyridine salt, benzenesulfonic acid pyridine salt, p-toluenesulfonic acid pyridine salt, trifluoromethanesulfonic acid pyridine salt, or trifluoroacetic acid is preferable, and methanesulfonic acid pyridine salt is particularly preferable. When the siloxane resin composition is used for a low refractive index film, from the viewpoint of reducing the refractive index, trifluoromethanesulfonic acid pyridine salt, trifluoroethanesulfonic acid pyridine salt, trifluoropropanesulfonic acid pyridine salt, or trifluoroacetic acid pyridine salt is preferable, and trifluoromethanesulfonic acid pyridine salt or trifluoroacetic acid pyridine salt is particularly preferably used.

As the (b) organic salt, a commercially available organic salt may be used, or a synthesized organic salt may be used. As a synthesis method, for example, the organic acid and dehydrated THF are stirred under nitrogen, and the salts precipitated by adding the amine dropwise while cooling with ice are obtained by filtration, followed by vacuum drying.

### (c) Solvent

The (c) solvent has a function of adjusting the viscosity of the resin composition to a range suitable for coating and improving coating uniformity.

Examples of the solvent include alcohols such as ethanol, propanol, isopropanol, and diacetone alcohol; glycols such as ethylene glycol and propylene glycol; ethers such as ethylene glycol monomethyl ether, ethylene glycol monoethyl ether, propylene glycol monomethyl ether, propylene glycol monoethyl ether, propylene glycol monopropyl ether, and propylene glycol monobutyl ether; ketones such as methyl ethyl ketone, acetylacetone, methyl propyl ketone, methyl butyl ketone, methyl isobutyl ketone, diisobutyl ketone, and cyclopentanone; amides such as dimethylformamide and dimethylacetamide; acetates such as ethyl acetate, propyl acetate, butyl acetate, isobutyl acetate, ethylene glycol monoethyl ether acetate, propylene glycol monomethyl ether acetate, 3-methoxybutyl acetate, 3-methyl-3-methoxybutyl acetate, methyl lactate, ethyl lactate, and butyl lactate; aromatic or aliphatic hydrocarbons such as toluene, xylene, hexane, and cyclohexane, γ-butyrolactone, N-methyl-2-pyrrolidone, and dimethyl sulfoxide. Two or more of these solvents may be contained. From the viewpoint of coating properties, it is preferable to combine a solvent having a boiling point of higher than 150° C. and 250° C. or lower at atmospheric pressure with a solvent having a boiling point of 150° C. or lower, and it is preferable to combine diacetone alcohol as a solvent having a boiling point of higher than 150° C. and 250° C. or lower at atmospheric pressure with propylene glycol monomethyl ether as a solvent having a boiling point of 150° C. or lower.

The content of the solvent can be arbitrarily set according to a coating method or the like. For example, in forming a film by spin coating, in general, the content of the solvent is 50% by mass or more and 95% by mass or less in the resin composition for forming a cured film.

### (d) Photosensitizer

The siloxane resin composition for forming a cured film preferably has (d) a photosensitizer in the example of requiring photosensitivity. In the example of imparting negative photosensitivity, a photopolymerization initiator is preferably contained as the (d) photosensitizer, and a high definition pattern can be formed. In the example of imparting negative photosensitivity, it is preferable to further contain a photopolymerizable compound. On the other hand, in the example of imparting positive photosensitivity, it is preferable to contain a quinone diazide compound as the (d) photosensitizer.

Any photopolymerization initiator may be used as long as it decomposes and/or reacts by irradiation with light (including ultraviolet ray and electron beam) to generate radicals. Examples thereof include α-aminoalkylphenone compounds such as 2-methyl-[4-(methylthio)phenyl]-2-morpholinopropane-1-one, 2-dimethylamino-2-(4-methylbenzyl)-1-(4-morpholine-4-yl-phenyl)-butane-1-one, and 2-benzyl-2-dimethylamino-1-(4-morpholinophenyl)-butanone-1; acylphosphine oxide compounds such as 2,4,6-trimethylbenzoylphenylphosphine oxide, bis(2,4,6-trimethylbenzoyl)-phenylphosphine oxide, and bis(2,6-dimethoxybenzoyl)-(2,4,4-trimethylpentyl)-phosphine oxide; oxime ester compounds such as 1-phenyl-1,2-propanedione-2-(O-ethoxycarbonyl) oxime, 1,2-octanedione-1-[4-(phenylthio)-2-(O-benzoyloxime)], 1-phenyl-1,2-butadione-2-(O-methoxycarbonyl) oxime, 1,3-diphenylpropanetrione-2-(O-ethoxycarbonyl) oxime, and ethanone-1-[9-ethyl-6-(2-methylbenzoyl)-9H-carbazole-3-yl]-1-(O-acetyloxime); benzyl ketal compounds such as benzyl dimethyl ketal; α-hydroxy ketone compounds such as 2-hydroxy-2-methyl-1-phenylpropane-1-one, 1-(4-isopropylphenyl)-2-hydroxy-2-methylpropane-1-one, 4-(2-hydroxyethoxy)phenyl-(2-hydroxy-2-propyl) ketone, and 1-hydroxycyclohexyl-phenyl ketone; benzophenone compounds such as benzophenone, 4,4-bis(dimethylamino)benzophenone, 4,4-bis(diethylamino)benzophenone, methyl o-benzoylbenzoate, 4-phenylbenzophenone, 4,4-dichlorobenzophenone, hydroxybenzophenone, 4-benzoyl-4′-methyl-diphenylsulfide, alkylated benzophenone, and 3,3′,4,4′-tetra(t-butylperoxycarbonyl)benzophenone; acetophenone compounds such as 2,2-diethoxyacetophenone, 2,3-diethoxyacetophenone, 4-t-butyldichloroacetophenone, benzalacetophenone, and 4-azidobenzalacetophenone; aromatic ketoester compounds such as methyl 2-phenyl-2-oxyacetate; and benzoic acid ester compounds such as ethyl 4-dimethylaminobenzoate, (2-ethyl) hexyl 4-dimethylaminobenzoate, ethyl 4-diethylaminobenzoate, and methyl 2-benzoylbenzoate. Two or more of these solvents may be contained.

The content of the photopolymerization initiator in the siloxane resin composition for forming a cured film is preferably 0.01% by mass or more, more preferably 1% by mass or more, in the solid content from the viewpoint of effectively promoting radical curing. On the other hand, from the viewpoint of suppressing elution of the remaining photopolymerization initiator and the like, the content of the photopolymerization initiator is preferably 20% by mass or less, more preferably 10% by mass, in the solid content.

The photopolymerizable compound refers to a compound having two or more ethylenic unsaturated double bonds in the molecule. In consideration of ease of radical polymerization, the photopolymerizable compound preferably has a (meth)acrylic group.

Examples of the photopolymerizable compound include diethylene glycol diacrylate, triethylene glycol diacrylate, tetraethylene glycol diacrylate, diethylene glycol dimethacrylate, triethylene glycol dimethacrylate, tetraethylene glycol dimethacrylate, trimethylolpropane diacrylate, trimethylolpropane triacrylate, trimethylolpropane dimethacrylate, trimethylolpropane trimethacrylate, 1,3-butanediol diacrylate, 1,3-butanediol dimethacrylate, neopentyl glycol diacrylate, 1,4-butanediol diacrylate, 1,4-butanediol dimethacrylate, 1,6-hexanediol diacrylate, 1,9-nonanediol dimethacrylate, 1,10-decanediol dimethacrylate, dimethylol-tricyclodecane diacrylate, pentaerythritol triacrylate, pentaerythritol tetraacrylate, pentaerythritol trimethacrylate, pentaerythritol tetramethacrylate, dipentaerythritol pentaacrylate, dipentaerythritol hexaacrylate, tripentaerythritol heptaacrylate, tripentaerythritol octaacrylate, tetrapentaerythritol nonaacrylate, tetrapentaerythritol decaacrylate, pentapentaerythritol undecaacrylate, pentapentaerythritol dodecaacrylate, tripentaerythritol heptamethacrylate, tripentaerythritol octamethacrylate, tetrapentaerythritol nonamethacrylate, tetrapentaerythritol decamethacrylate, pentapentaerythritol undecamethacrylate, pentapentaerythritol decamethacrylate, and dimethylol-tricyclodecane diacrylate. Two or more of these solvents may be contained.

The content of the photopolymerizable compound in the siloxane resin composition for forming a cured film is preferably 1% by mass or more, in the solid content from the viewpoint of effectively promoting radical curing. On the other hand, from the viewpoint of suppressing the excessive reaction of radicals and improving the resolution, the content of the photopolymerizable compound is preferably 50% by mass or less in the solid content.

As the quinone diazide compound, a compound having a phenolic hydroxyl group bonded to naphthoquinonediazidesulfonic acid through ester linkage is preferable. Examples of the compound having a phenolic hydroxyl group used herein include BIS-Z, TekP-4HBPA (tetrakis P-DO-BPA), TrIsP-HAP, TrIsP-PA, BIsRS-2P, and BIsRS-3P (all are trade names, manufactured by Honshu Chemical Industry Co., Ltd.), BIR-PC, BIR-PTBP, and BIR-BIPC-F (all are trade names, manufactured by Asahi Organic Chemicals Industry Co., Ltd.), 4,4′-sulfonyldiphenol, and BPFL (trade name, manufactured by JFE Chemical Corporation). As the quinone diazide compound, those obtained by introducing 4-naphthoquinone diazide sulfonic acid or 5-naphthoquinone diazide sulfonic acid into these compounds having a phenolic hydroxyl group by an ester bond are preferable, and examples thereof include THP-17 and TDF-517 (trade name, manufactured by Toyo Gosei Co., Ltd.) and SBF-525 (trade name, manufactured by AZ Electronic Materials Co., Ltd.).

The content of the quinone diazide compound in the siloxane resin composition for forming a cured film is preferably 0.5% by mass or more, more preferably 1% by mass or more, in the solid content from the viewpoint of improving sensitivity. On the other hand, the content of the quinone diazide compound is preferably 25% by mass or less, more preferably 20% by mass or less, in the solid content from the viewpoint of resolution.

The siloxane resin composition for forming a cured film may contain an ultraviolet absorber, a polymerization inhibitor, a surfactant, an adhesion improving agent, nanoparticles, a pigment and the like as necessary.

When the siloxane resin composition for forming a cured film contains an ultraviolet absorber, light resistance can be improved. As the ultraviolet absorber, from the viewpoint of transparency and non-stainability, benzotriazole-based compounds such as 2-(2H-benzotriazole-2-yl) phenol, 2-(2H-benzotriazole-2-yl)-4,6-tert-pentylphenol, 2-(2H-benzotriazole-2-yl)-4-(1,1,3,3-tetramethylbutyl) phenol, 2 (2H-benzotriazole-2-yl)-6-dodecyl-4-methylphenol, and 2-(2′-hydroxy-5′-methacryloxyethylphenyl)-2H-benzotriazole; benzophenone-based compound such as 2-hydroxy-4-methoxybenzophenone; triazine-based compounds such as 2-(4,6-diphenyl-1,3,5 triazine-2-yl)-5-[(hexyl)oxy]-phenol; and the like are preferably used.

When the siloxane resin composition for forming a cured film contains a polymerization inhibitor, resolution can be further improved. Examples of the polymerization inhibitor include di-t-butylhydroxytoluene, butylhydroxyanisole, 4-methoxyphenol, 1,4-benzoquinone, and t-butylcatechol. Examples of commercially available polymerization inhibitors include “IRGANOX” (registered trademark) 1010, 1035, 1076, 1098, 1135, 1330, 1726, 1425, 1520, 245, 259, 3114, 565, and 295 (all are trade names, manufactured by BASF Japan Ltd.). Two or more of these solvents may be contained.

When the siloxane resin composition for forming a cured film contains a surfactant, the flowability during the application can be improved. Examples of the surfactant include fluorochemical surfactants such as “MEGAFACE” (registered trademark) F142D, F172, F173, F183, F445, F470, F475, and F477 (the above are trade names, manufactured by Dainippon Ink and Chemicals, Incorporated); fluorine surfactant such as NBX-15, and FTX-218 (the above are trade names, manufactured by NEOS COMPANY LIMITED); silicone surfactants such as “BYK” (registered trademark) 333, 301, 331, 345, and 307 (the above are trade names, manufactured by BYK Japan KK); polyalkylene oxide surfactants; and poly(meth)acrylate surfactants. Two or more of these solvents may be contained.

When the siloxane resin composition for forming a cured film contains an adhesion improving agent, adhesion to a base substrate can be improved. Examples of the adhesion improving agent include an alicyclic epoxy compound and a silane coupling agent. Among them, an alicyclic epoxy compound is preferable from the viewpoint of heat resistance.

Examples of the alicyclic epoxy compound include 3′,4′-epoxycyclohexymethyl-3,4-epoxycyclohexanecarboxylate, 1,2-epoxy-4-(2-oxiranyl)cyclohexane adduct of 2,2-bis(hydroxymethyl)-1-butanol, ε-caprolactone-modified 3′,4′-epoxycyclohexylmethyl 3′,4′-epoxycyclohexanecarboxylate, 1,2-epoxy-4-vinylcyclohexane, tetra(3,4-epoxycyclohexylmethyl) butanetetracarboxylate modified ε-caprolactone, 3,4-epoxycyclohexylmethyl methacrylate, hydrogenated bisphenol A diglycidyl ether, hydrogenated bisphenol F diglycidyl ether, hydrogenated bisphenol E diglycidyl ether, hydrogenated bisphenol A bis(propylene glycol glycidyl ether) ether, hydrogenated bisphenol A bis(ethylene glycol glycidyl ether) ether, 1,4-cyclohexane dicarboxylic acid diglycidyl, and 1,4-cyclohexane dimethanol diglycidyl ether. Two or more of these solvents may be contained.

The content of the adhesion improving agent in the siloxane resin composition for forming a cured film is preferably 0.1% by mass or more, more preferably 1% by mass or more, in the solid content from the viewpoint of further improving the adhesion to the base substrate. On the other hand, the content of the adhesion improving agent is preferably 20% by mass or less, more preferably 10% by mass or less, in the solid content from the viewpoint of patternability.

When the siloxane resin composition for forming a cured film contains nanoparticles, the refractive index of the cured film can be adjusted. Examples of the nanoparticles include silica particles, magnesium fluoride particles, titania particles, and zirconia particles. Two or more of these solvents may be contained. In decreasing the refractive index, silica particles and magnesium fluoride particles are preferably contained, and in increasing the refractive index, titania particles and zirconia particles are preferably contained.

When the siloxane resin composition for forming a cured film contains a pigment, the reflectivity and the light shielding properties of the cured film can be adjusted.

When it is desired to improve the reflectivity of the cured film, it is preferable to contain a white pigment. Examples of the white pigment include titanium dioxide, zirconium oxide, zinc oxide, barium sulfate, and a composite compound thereof. Two or more of these solvents may be contained.

When it is desired to improve the light shielding properties of the cured film at a specific wavelength, it is preferable to contain a light shielding pigment such as a red pigment, a blue pigment, a black pigment, a green pigment, or a yellow pigment. When it is desired to achieve both the reflectivity and the light shielding properties, it is preferable to contain both a white pigment and a light shielding pigment.

Examples of the red pigment include Pigment Red (hereinafter “PR”) PR177, PR179, PR180, PR192, PR209, PR227, PR228, PR240, and PR254. Two or more of these solvents may be contained.

Examples of the blue pigment include Pigment Blue (hereinafter “PB”) 15, PB15:3, PB15:4, PB15:6, PB22, PB60, and PB64. Two or more of these solvents may be contained.

Examples of the black pigment include black organic pigments, mixed color organic pigments, and black inorganic pigments. Examples of the black organic pigments include carbon black, perylene black, aniline black, and benzofuranone-based pigments. These may be coated with a resin. Examples of the mixed color organic pigments include pigments produced by mixing two or more pigments selected from colors of red, blue, green, purple, yellow, magenta, and cyan to make a pseudo black color. Among them, a mixed pigment of a red pigment and a blue pigment is preferable from the viewpoint of achieving both an appropriately high OD value and patternability. The mass ratio of the red pigment and the blue pigment in the mixed pigment is preferably 20/80 to 80/20, more preferably 30/70 to 70/30. Examples of the black inorganic pigments include graphite; fine particles of metals such as titanium, copper, iron, manganese, cobalt, chromium, nickel, zirconium, zinc, calcium, silver, gold, platinum, and palladium; metal oxides; metal composite oxides, metal sulfides, metal nitrides; metal oxynitrides; and metal carbides. Two or more of these solvents may be contained.

Examples of the green pigment include C.I. Pigment Green (hereinafter abbreviated as “PG”) 7, PG36, PG58, PG37, and PG59. Two or more of these solvents may be contained.

Examples of the yellow pigment include Pigment Yellow (hereinafter “PY”) PYPY150, PY153, PY154, PY166, PY168, and PY185. Two or more of these solvents may be contained.

The siloxane resin composition for forming a cured film may contain a resin other than the polysiloxane. When the resin other than the polysiloxane is used, the film properties that are insufficient with the polysiloxane can be complemented, for example, the tackiness after prebaking may be improved. Examples of the resin other than the polysiloxane include a polyimide, a polyimide precursor, a polybenzoxazole, a polybenzoxazole precursor, a (meth)acrylic polymer, and a cardo resin.

When the (a) polysiloxane contained in the siloxane resin composition for forming a cured film has an aromatic group and/or a substituted aromatic group in a side chain group, the content of each of benzene, toluene, xylene, aniline, styrene, and naphthalene in the resin composition is preferably less than 1 ppm.

Conventionally, when a polysiloxane containing an aromatic group and/or a substituted aromatic group in a side chain group is obtained by a condensation reaction using a strongly acidic catalyst such as phosphoric acid or a strongly basic catalyst, or when the polysiloxane is used together with an acid generator and a base generator that generate a strong acid and a strong base, there has been a problem in that a part of a bond between a Si atom and the side chain group in the polysiloxane is broken, and a trace amount of impurities derived from the side chain group is generated. That is, for example, when a polysiloxane having a phenyl group, a tolyl group, a xylyl group, a phenylamino group, a styryl group, or a naphthyl group in a side chain group is obtained by a condensation reaction with a phosphoric acid catalyst, there is a problem in that benzene, toluene, xylene, aniline, styrene, or naphthalene is contained in an amount of 1 ppm or more as impurities.

On the other hand, in the siloxane resin composition for forming a cured film, a polysiloxane condensed using the (b) organic salt having a pH value in a 1.0% by mass aqueous solution of 3.0 to 5.5 is used as a catalyst, or the (b) organic salt is used instead of the acid generator and the base generator so that the cleavage reaction of the side chain group described above does not occur, and the content of the impurities can be suppressed to less than 1 ppm.

In the siloxane resin composition for forming a cured film, the cured film is preferably a permanent film, that is, the resin composition is preferably a resin composition for forming a cured film. The permanent film is not a film to be removed during a manufacturing process like a general resist layer, but a cured film permanently remaining in a product.

Next, a cured film will be described.

The cured film is obtained by curing the resin composition for forming a cured film. The cured film is preferably used as a permanent film.

Another aspect of the cured film is a cured film in which an atomicity ratio of N to Si as measured by a scanning electron microscope (SEM-EDX) is 0.005 or more and 0.200 or less, and an atomicity ratio of at least one atom selected from S, P, and F to Si is 0.005 or more and 0.200 or less. When the atomicity ratio is within these ranges, both solvent resistance and transmittivity of the film can be achieved. The atomicity ratio of N to Si and the atomicity ratio of at least one atom selected from S, P, and F to Si are preferably 0.010 or more and 0.150 or less, more preferably 0.015 or more and 0.100 or less.

The cured film can be obtained by curing the above-described siloxane resin composition for forming a cured film by a method described below.

The cured film can be suitably used in various hard coat films such as protective films for touch panels, insulating films for touch sensors, flattening films for TFTs intended for liquid crystal and organic EL displays, metal wiring protective films, insulating films, antireflection films, optical filters, overcoats for color filters, column materials and the like.

The thickness of the cured film varies depending on applications, but is preferably 0.1 to 100 μm, more preferably 0.5 to 50 μm.

Next, a method of forming the cured film will be described with reference to examples.

The method of forming the cured film preferably includes a film formation step of applying the siloxane resin composition for forming a cured film onto a base substrate and drying the resin composition to obtain a dry film, and a heating step of curing the dry film by heating. The method may include an exposure step of exposing the obtained dry film after the film formation step.

Examples of the method of applying the siloxane resin composition for forming a cured film in the film formation step include a slit coating method, a spin coating method, and a spray coating method. Examples of the drier include a hot air oven and a hot plate. The drying temperature is preferably 80 to 130° C., and the drying time is preferably 1 to 30 minutes.

Examples of exposure equipment used in the exposure step include a proximity exposure machine. Examples of the active ray irradiated in the exposure step include infrared rays, visible rays, and ultraviolet rays, and ultraviolet rays are preferable. Examples of the light source thereof include low-pressure mercury lamps, high-pressure mercury lamps, ultra-high-pressure mercury lamps, halogen lamps, and bactericidal lamps, and ultra-high-pressure mercury lamps are preferable.

The exposure conditions can be appropriately selected depending on the thickness of the dry film to be exposed. In general, it is preferable to perform exposure at an exposure amount of 1 to 10,000 mJ/cm² using an ultra-high-pressure mercury lamp having an output of 1 to 100 mW/cm².

The heating step is a step of heating and curing the film. Examples of the heater include a hot plate and an oven. The heating temperature during the heating step is preferably 250° C. or lower, more preferably 240° C. or lower, from the viewpoint of suppressing the occurrence of cracks on the film to be heated. From the viewpoint of the degree of curing of the cured film, the heating temperature is preferably 100° C. or higher, more preferably 120° C. or higher. The heating time is preferably 15 minutes to 2 hours.

### Examples

Our compositions, films and methods will be described more concretely hereinafter with reference to examples and comparative examples. However, this disclosure is not limited to scopes thereof. Incidentally, of the compounds used, those whose abbreviations are used will be named below.
PGMEA: propylene glycol monomethyl ether acetate
DAA: diacetone alcohol
BHT: dibutylhydroxytoluene

The solid content concentration of the polysiloxane solution in Synthesis Examples 1 to 26 was determined by the following method. In an aluminum cup, 1.0 g of the polysiloxane solution was weighed and heated at 250° C. for 30 minutes using a hot plate to evaporate the liquid component. The mass of the solid content remaining in the aluminum cup after heating was weighed, and the solid content concentration was determined from the ratio to the mass before heating.

The weight average molecular weight of the polysiloxane solution in Synthesis Examples 1 to 26 was determined in terms of polystyrene by the following method.
Apparatus: GPC measuring apparatus with RI detector (2695) manufactured by Waters Corporation
Column: PLgelMIXED-C column (Polymer Laboratories Ltd., 300 mm)×2 columns (connected in series)
Measurement temperature: 40° C.
Flow rate: 1 mL/min
Solvent: 0.5% by mass solution of tetrahydrofuran (THF)
Reference material: polystyrene
Detection mode: RI

The content ratio of each repeating unit in the polysiloxane in Synthesis Examples 1 to 26 was determined by the following method. A polysiloxane solution was injected into an NMR sample tube made of “Teflon” (registered trademark) having a diameter of 10 mm, ²⁹Si-NMR measurement was performed, and the content ratio of each repeating unit was calculated from the ratio of the integral value of Si derived from a specific organosilane to the integral value of the entire Si derived from the organosilane. ²⁹Si-NMR measurement conditions are indicated below. Apparatus: nuclear magnetic resonance apparatus (JNM-GX270; manufactured by JEOL Ltd.) Measurement method: gated decoupling method
Measurement nucleus frequency: 53.6693 MHZ (²⁹Si nucleus)
Spectrum width: 20,000 Hz
Pulse width: 12 μs (45° pulse)
Pulse repetition time: 30.0 seconds
Solvent: acetone-d6
Reference matter: tetramethylsilane
Measurement temperature: 23° C.
Specimen rotation speed: 0.0 Hz

### Synthesis Example 1 Polysiloxane (A-1) Solution

In a 1000 ml three-necked flask, 203.13 g (0.831 mol) of diphenyldimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.475 g of BHT, and 308.45 g of PGMEA were charged. While the resulting mixture was stirred at 40° C., a catalyst aqueous solution obtained by dissolving 3.887 g (1.0% by mass based on the charged monomers) of p-toluenesulfonic acid pyridine salt in 76.39 g of water was added over 30 minutes. Thereafter, the flask was immersed in an oil bath at 70° C. and stirred for 60 minutes, and then the temperature of the oil bath was raised to 115° C. over 30 minutes. The solution temperature (internal temperature) reached 100° C. after 1 hour from the start of temperature increase, and then the mixture was heated and stirred for 2 hours (internal temperature was 100 to 110° C.) to obtain a polysiloxane solution. During the temperature increase and heating/stirring, a mixed gas of 95 vol % of nitrogen and 5 vol % of oxygen was flowed at 0.05 liter/min. During the reaction, a total of 173.99 g of methanol and water as by-products were distilled out. PGMEA was added to the obtained polysiloxane solution so that the solid content concentration was 50% by mass to obtain a polysiloxane (A-1) solution without particularly removing the catalyst. The weight average molecular weight of the obtained polysiloxane (A-1) was 5,000. In the polysiloxane (A-1), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 2 Polysiloxane (A-2) Solution

A polysiloxane (A-2) solution was obtained in the same manner as in Synthesis Example 1, except that a catalyst aqueous solution obtained by dissolving 3.887 g (1.0% by mass based on the charged monomers) of methanesulfonic acid pyridine salt in 76.39 g of water was used as the catalyst aqueous solution. The weight average molecular weight of the obtained polysiloxane (A-2) was 5,000. In the polysiloxane (A-2), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 3 Polysiloxane (A-3) Solution

A polysiloxane (A-3) solution was obtained in the same manner as in Synthesis Example 1, except that a catalyst aqueous solution obtained by dissolving 3.887 g (1.0% by mass based on the charged monomers) of trifluoromethanesulfonic acid pyridine salt in 76.39 g of water was used as the catalyst aqueous solution. The weight average molecular weight of the obtained polysiloxane (A-3) was 5,000. In the polysiloxane (A-3), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 4 Polysiloxane (A-4) Solution

A polysiloxane (A-3) solution was obtained in the same manner as in Synthesis Example 1, except that a catalyst aqueous solution obtained by dissolving 3.887 g (1.0% by mass based on the charged monomers) of trifluoroacetic acid pyridine salt in 76.39 g of water was used as the catalyst aqueous solution. The weight average molecular weight of the obtained polysiloxane (A-4) was 5,000. In the polysiloxane (A-4), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 5 Polysiloxane (A-5) Solution

A polysiloxane (A-5) solution was obtained in the same manner as in Synthesis Example 1, except that a catalyst aqueous solution obtained by dissolving 3.887 g (1.0% by mass based on the charged monomers) of benzenesulfonic acid pyridine salt in 76.39 g of water was used as the catalyst aqueous solution. The weight average molecular weight of the obtained polysiloxane (A-5) was 5,000. In the polysiloxane (A-5), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 6 Polysiloxane (A-6) Solution

A polysiloxane (A-6) solution was obtained in the same manner as in Synthesis Example 1, except that a catalyst aqueous solution obtained by dissolving 3.887 g (1.0% by mass based on the charged monomers) of benzenesulfonic acid aniline salt in 76.39 g of water was used as the catalyst aqueous solution. The weight average molecular weight of the obtained polysiloxane (A-6) was 5,000. In the polysiloxane (A-6), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 7 Polysiloxane (A-7) Solution

A polysiloxane (A-7) solution was obtained in the same manner as in Synthesis Example 1, except that a catalyst aqueous solution obtained by dissolving 3.887 g (1.0% by mass based on the charged monomers) of tetraethylammonium p-toluenesulfonate in 76.39 g of water was used as the catalyst aqueous solution. The weight average molecular weight of the obtained polysiloxane (A-7) was 1,200. In the polysiloxane (A-7), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 8 Polysiloxane (A-8) Solution

In a 1000 ml three-necked flask, 213.82 g (0.875 mol) of diphenyldimethoxysilane, 43.12 g (0.175 mol) of 3-(3,4-epoxycyclohexyl) propyltrimethoxysilane, 68.86 g (0.263 mol) of tetraethoxysilane, 59.59 g (0.438 mol) of methyltrimethoxysilane, 1.413 g of BHT, and 298.06 g of PGMEA were charged. While the resulting mixture was stirred at 40° C., a catalyst aqueous solution obtained by dissolving 3.887 g (1.0% by mass based on the charged monomers) of p-toluenesulfonic acid pyridine salt in 76.39 g of water was added over 30 minutes. Thereafter, the flask was immersed in an oil bath at 70° C. and stirred for 60 minutes, and then the temperature of the oil bath was raised to 115° C. over 30 minutes. The solution temperature (internal temperature) reached 100° C. after 1 hour from the start of temperature increase, and then the mixture was heated and stirred for 2 hours (internal temperature was 100 to 110° C.) to obtain a polysiloxane solution. During the temperature increase and heating/stirring, a mixed gas of 95 vol % of nitrogen and 5 vol % of oxygen was flowed at 0.05 liter/min. During the reaction, a total of 282.58 g of methanol and water as by-products were distilled out. PGMEA was added to the obtained polysiloxane solution so that the solid content concentration was 50% by mass to obtain a polysiloxane (A-8) solution. The weight average molecular weight of the obtained polysiloxane (A-8) was 8,000. In the polysiloxane (A-8), the molar ratios of the repeating units derived from diphenyldimethoxysilane, 3-(3,4-epoxycyclohexyl) propyltrimethoxysilane, tetraethoxysilane, and methyltrimethoxysilane were 50 mol %, 10 mol %, 15 mol %, and 25 mol %, respectively.

### Synthesis Example 9 Polysiloxane (A-9) Solution

A polysiloxane (A-9) solution was obtained in the same manner as in Synthesis Example 1, except that a catalyst aqueous solution obtained by dissolving 3.887 g (1.0% by mass based on the charged monomers) of phosphoric acid in 76.39 g of water was used as the catalyst aqueous solution. The weight average molecular weight of the obtained polysiloxane (A-9) was 4,200. In the polysiloxane (A-9), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 10 Polysiloxane (A-10) Solution

To 100 g of the polysiloxane (A-9) solution, 2.00 g of a weakly basic ion exchange resin (“Amberlite” (registered trademark) A21 manufactured by ORGANO CORPORATION (hereinafter, “A21”)) and 2.00 g of a weakly acidic ion exchange resin (“Amberlite” (registered trademark) 15JWET manufactured by ORGANO CORPORATION (hereinafter “15J”)) were added, and the resulting mixture was stirred at room temperature for 12 hours. Thereafter, the ion exchange resin was removed by filtration to obtain a polysiloxane (A-10) solution. The weight average molecular weight of the obtained polysiloxane (A-10) was 4,500. In the polysiloxane (A-10), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 11 Polysiloxane (A-11) Solution

A polysiloxane (A-11) solution was obtained in the same manner as in Synthesis Example 1, except that a catalyst aqueous solution obtained by dissolving 0.389 g (0.1% by mass based on the charged monomers) of p-toluenesulfonic acid pyridine salt in 76.39 g of water was used as the catalyst aqueous solution and the addition amount of PGMEA was changed to 311.95 g. The weight average molecular weight of the obtained polysiloxane (A-11) was 2,500. In the polysiloxane (A-11), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 12 Polysiloxane (A-12) Solution

A polysiloxane (A-12) solution was obtained in the same manner as in Synthesis Example 1, except that a catalyst aqueous solution obtained by dissolving 11.66 g (3.0% by mass based on the charged monomers) of p-toluenesulfonic acid pyridine salt in 76.39 g of water was used as the catalyst aqueous solution and the addition amount of PGMEA was changed to 300.68 g. The weight average molecular weight of the obtained polysiloxane (A-12) was 6,500. In the polysiloxane (A-12), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 13 Polysiloxane (A-13) Solution

A polysiloxane (A-13) solution was obtained in the same manner as in Synthesis Example 1, except that a catalyst aqueous solution obtained by dissolving 0.039 g (0.01% by mass based on the charged monomers) of p-toluenesulfonic acid pyridine salt in 76.39 g of water was used as the catalyst aqueous solution and the addition amount of PGMEA was changed to 312.30 g. The weight average molecular weight of the obtained polysiloxane (A-13) was 6,500. In the polysiloxane (A-13), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 14 Polysiloxane (A-14) Solution

A polysiloxane (A-14) solution was obtained in the same manner as in Synthesis Example 1, except that a catalyst aqueous solution obtained by dissolving 21.38 g (5.5% by mass based on the charged monomers) of p-toluenesulfonic acid pyridine salt in 76.39 g of water was used as the catalyst aqueous solution and the addition amount of PGMEA was changed to 290.96 g. The weight average molecular weight of the obtained polysiloxane (A-14) was 6,500. In the polysiloxane (A-14), the molar ratios of the repeating units derived from diphenyldimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, and 10 mol %, respectively.

### Synthesis Example 15 Polysiloxane (A-15) Solution

In a 1000 ml three-necked flask, 47.67 g (0.350 mol) of methyltrimethoxysilane, 152.11 g (0.613 mol) of 3-methacryloxypropyltrimethoxysilane, 152.74 g (0.700 mol) of trifluoropropyltrimethoxysilane, 22.95 g (0.088 mol) of 3-trimethoxysilylpropylsuccinic anhydride, 1.282 g of BHT, and 275.65 g of PGMEA were charged. While the resulting mixture was stirred at 40° C., a catalyst aqueous solution obtained by dissolving 3.755 g (1.0% by mass based on the charged monomers) of p-toluenesulfonic acid pyridine salt in 96.08 g of water was added over 30 minutes. Thereafter, a polysiloxane (A-15) solution was obtained in the same manner as in Synthesis Example 1. The weight average molecular weight of the obtained polysiloxane (A-15) was 4,500. In the polysiloxane (A-15), the molar ratios of the repeating units derived from methyltrimethoxysilane, 3-methacryloxypropyltrimethoxysilane, trifluoropropyltrimethoxysilane, and 3-trimethoxysilylpropylsuccinic anhydride were 35 mol %, 20 mol %, 40 mol %, and 5 mol %, respectively.

### Synthesis Example 16 Polysiloxane (A-16) Solution

A polysiloxane (A-16) solution was obtained in the same manner as in Synthesis Example 15, except that a catalyst aqueous solution obtained by dissolving 3.755 g (1.0% by mass based on the charged monomers) of trifluoroacetic acid pyridine salt in 96.08 g of water was used as the catalyst aqueous solution. The weight average molecular weight of the obtained polysiloxane (A-16) was 4,500. In the polysiloxane (A-16), the molar ratios of the repeating units derived from methyltrimethoxysilane, 3-methacryloxypropyltrimethoxysilane, trifluoropropyltrimethoxysilane, and 3-trimethoxysilylpropylsuccinic anhydride were 35 mol %, 20 mol %, 40 mol %, and 5 mol %, respectively.

### Synthesis Example 17 Polysiloxane (A-17) Solution

In a 1000 ml three-necked flask, 176.49 g (0.831 mol) of p-tolyltrimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.245 g of BHT, and 267.12 g of PGMEA were charged. While the resulting mixture was stirred at 40° C., a catalyst aqueous solution obtained by dissolving 3.621 g (1.0% by mass based on the charged monomers) of methanesulfonic acid pyridine salt in 91.35 g of water was added over 30 minutes. Thereafter, a polysiloxane (A-17) solution was obtained in the same manner as in Synthesis Example 1. The weight average molecular weight of the obtained polysiloxane (A-17) was 4,500. In the polysiloxane (A-17), the molar ratios of the repeating units derived from p-tolyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 18 Polysiloxane (A-18) Solution

In a 1000 ml three-necked flask, 188.15 g (0.831 mol) of 3,5-dimethylphenyltrimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.245 g of BHT, and 278.67 g of PGMEA were charged. While the resulting mixture was stirred at 40° C., a catalyst aqueous solution obtained by dissolving 3.738 g (1.0% by mass based on the charged monomers) of methanesulfonic acid pyridine salt in 91.35 g of water was added over 30 minutes. Thereafter, a polysiloxane (A-18) solution was obtained in the same manner as in Synthesis Example 1. The weight average molecular weight of the obtained polysiloxane (A-18) was 4,000. In the polysiloxane (A-18), the molar ratios of the repeating units derived from 3,5-dimethylphenyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 19 Polysiloxane (A-19) Solution

In a 1000 ml three-necked flask, 177.31 g (0.831 mol) of M-aminophenyltrimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.249 g of BHT, and 267.94 g of PGMEA were charged. While the resulting mixture was stirred at 40° C., a catalyst aqueous solution obtained by dissolving 3.629 g (1.0% by mass based on the charged monomers) of methanesulfonic acid pyridine salt in 91.35 g of water was added over 30 minutes. Thereafter, a polysiloxane (A-19) solution was obtained in the same manner as in Synthesis Example 1. The weight average molecular weight of the obtained polysiloxane (A-19) was 5,000. In the polysiloxane (A-19), the molar ratios of the repeating units derived from M-aminophenyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 20 Polysiloxane (A-20) Solution

In a 1000 ml three-necked flask, 186.45 g (0.831 mol) of p-styryltrimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.295 g of BHT, and 276.98 g of PGMEA were charged. While the resulting mixture was stirred at 40° C., a catalyst aqueous solution obtained by dissolving 3.721 g (1.0% by mass based on the charged monomers) of methanesulfonic acid pyridine salt in 91.35 g of water was added over 30 minutes. Thereafter, a polysiloxane (A-20) solution was obtained in the same manner as in Synthesis Example 1. The weight average molecular weight of the obtained polysiloxane (A-20) was 6,600. In the polysiloxane (A-20), the molar ratios of the repeating units derived from p-styryltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 21 Polysiloxane (A-21) Solution

In a 1000 ml three-necked flask, 206.44 g (0.831 mol) of 1-naphthyltrimethoxysilane, 76.06 g (0.306 mol) of 3-methacryloxypropyltrimethoxysilane, 21.56 g (0.088 mol) of 3-(3,4-epoxycyclohexyl) propyltrimethoxysilane, 42.08 g (0.350 mol) of dimethyldimethoxysilane, 45.91 g (0.175 mol) of 3-trimethoxysilylpropylsuccinic anhydride, 1.396 g of BHT, and 296.77 g of PGMEA were charged. While the resulting mixture was stirred at 40° C., a catalyst aqueous solution obtained by dissolving 3.920 g (1.0% by mass based on the charged monomers) of methanesulfonic acid pyridine salt in 91.35 g of water was added over 30 minutes. Thereafter, a polysiloxane (A-21) solution was obtained in the same manner as in Synthesis Example 1. The weight average molecular weight of the obtained polysiloxane (A-21) was 3,000. In the polysiloxane (A-21), the molar ratios of the repeating units derived from 1-naphthyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 22 Polysiloxane (A-22) Solution

The reaction was performed in the same manner as in Synthesis Example 17, except that a catalyst aqueous solution obtained by adding 3.621 g (1.0% by mass based on the charged monomers) of phosphoric acid to 91.35 g of water was used as the catalyst aqueous solution. To 100 g of the obtained solution, 2.00 g of A21 and 2.00 g of 15JWET were added as the ion exchange resin, and the resulting mixture was stirred at room temperature for 12 hours. Thereafter, the ion exchange resin was removed by filtration to obtain a polysiloxane (A-22) solution. The weight average molecular weight of the obtained polysiloxane (A-22) was 4,500. In the polysiloxane (A-22), the molar ratios of the repeating units derived from p-tolyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 23 Polysiloxane (A-23) Solution

The reaction was performed in the same manner as in Synthesis Example 18, except that a catalyst aqueous solution obtained by adding 3.621 g (1.0% by mass based on the charged monomers) of phosphoric acid to 91.35 g of water was used as the catalyst aqueous solution. To 100 g of the obtained solution, 2.00 g of A21 and 2.00 g of 15JWET were added as the ion exchange resin, and the resulting mixture was stirred at room temperature for 12 hours. Thereafter, the ion exchange resin was removed by filtration to obtain a polysiloxane (A-23) solution. The weight average molecular weight of the obtained polysiloxane (A-23) was 4,500. In the polysiloxane (A-23), the molar ratios of the repeating units derived from 3,5-dimethylphenyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 24 Polysiloxane (A-24) Solution

The reaction was performed in the same manner as in Synthesis Example 19, except that a catalyst aqueous solution obtained by adding 3.621 g (1.0% by mass based on the charged monomers) of phosphoric acid to 91.35 g of water was used as the catalyst aqueous solution. To 100 g of the obtained solution, 2.00 g of A21 and 2.00 g of 15JWET were added as the ion exchange resin, and the resulting mixture was stirred at room temperature for 12 hours. Thereafter, the ion exchange resin was removed by filtration to obtain a polysiloxane (A-23) solution. The weight average molecular weight of the obtained polysiloxane (A-24) was 4,500. In the polysiloxane (A-24), the molar ratios of the repeating units derived from M-aminophenyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 25 Polysiloxane (A-25) Solution

The reaction was performed in the same manner as in Synthesis Example 20, except that a catalyst aqueous solution obtained by adding 3.621 g (1.0% by mass based on the charged monomers) of phosphoric acid to 91.35 g of water was used as the catalyst aqueous solution. To 100 g of the obtained solution, 2.00 g of A21 and 2.00 g of 15JWET were added as the ion exchange resin, and the resulting mixture was stirred at room temperature for 12 hours. Thereafter, the ion exchange resin was removed by filtration to obtain a polysiloxane (A-23) solution. The weight average molecular weight of the obtained polysiloxane (A-25) was 6,500. In the polysiloxane (A-25), the molar ratios of the repeating units derived from p-styryltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

### Synthesis Example 26 Polysiloxane (A-26) Solution

The reaction was performed in the same manner as in Synthesis Example 21, except that a catalyst aqueous solution obtained by adding 3.621 g (1.0% by mass based on the charged monomers) of phosphoric acid to 91.35 g of water was used as the catalyst aqueous solution. To 100 g of the obtained solution, 2.00 g of A21 and 2.00 g of 15JWET were added as the ion exchange resin, and the resulting mixture was stirred at room temperature for 12 hours. Thereafter, the ion exchange resin was removed by filtration to obtain a polysiloxane (A-23) solution. The weight average molecular weight of the obtained polysiloxane (A-26) was 3,000. In the polysiloxane (A-26), the molar ratios of the repeating units derived from 1-naphthyltrimethoxysilane, 3-methacryloxypropyltrimethoxysilane, 3-(3,4-epoxycyclohexyl) propyltrimethoxysilane, dimethyldimethoxysilane, and 3-trimethoxysilylpropylsuccinic anhydride were 47.5 mol %, 17.5 mol %, 5 mol %, 20 mol %, 10 mol %, and 5 mol %, respectively.

The compositions employed in Synthesis Examples 1 to 26 are shown in Tables 1 to 4.

TABLE 1

| | | | | | Condensation catalyst | | |
|---|---|---|---|---|---|---|---|
| | | | | | (wt % with respect to | | |
| | | | | | silane raw material) | | |
| | | Raw material (mol %) | | | | pH | |
| | | Alkoxysilane | | | | value of | |
| | | constituting | | Other | | 1.0 wt % | Catalyst |
| | | general | | alkoxy | | aqueous | removal |
| | | formula (4) | Alkoxysilane constituting general formula (5) | silane | Catalyst species | solution | step |
| Synthesis | Poly | Diphenyldimeth- | 3-Methacryloxypropyltrimethoxysilane (17.5) | — | p-Toluene- | 3.6 | Not |
| Example | siloxane | oxysilane (47.5) | 3-(3,4-Epoxycyclohexyl)propyltrimethoxysilane (5) | | sulfonic acid | | performed |
| 1 | (A-1) | Dimethyldimeth- | 3-Trimethoxysilylpropylsuccinic anhydride (10) | | pyridine salt | | |
| | solution | oxysilane (20) | | | (1.0) | | |
| Synthesis | Poly | Diphenyldimeth- | 3-Methacryloxypropyltrimethoxysilane (17.5) | — | Methanesulfonic | 3.3 | Not |
| Example | siloxane | oxysilane (47.5) | 3-(3,4-Epoxycyclohexyl)propyltrimethoxysilane (5) | | acid | | performed |
| 2 | (A-2) | Dimethyldimeth- | 3-Trimethoxysilylpropylsuccinic anhydride (10) | | pyridine salt | | |
| | solution | oxysilane (20) | | | (1.0) | | |
| Synthesis | Poly | Diphenyldimeth- | 3-Methacryloxypropyltrimethoxysilane (17.5) | — | Trifluoromethane- | 3.5 | Not |
| Example | siloxane | oxysilane (47.5) | 3-(3,4-Epoxycyclohexyl)propyltrimethoxysilane (5) | | sulfonic acid | | performed |
| 3 | (A-3) | Dimethyldimeth- | 3-Trimethoxysilylpropylsuccinic anhydride (10) | | pyridine salt | | |
| | solution | oxysilane (20) | | | (1.0) | | |
| Synthesis | Poly | Diphenyldimeth- | 3-Methacryloxypropyltrimethoxysilane (17.5) | — | Trifluoroacetic | 3.3 | Not |
| Example | siloxane | oxysilane (47.5) | 3-(3,4-Epoxycyclohexyl)propyltrimethoxysilane (5) | | acid | | performed |
| 4 | (A-4) | Dimethyldimeth- | 3-Trimethoxysilylpropylsuccinic anhydride (10) | | pyridine salt | | |
| | solution | oxysilane (20) | | | (1.0) | | |
| Synthesis | Poly | Diphenyldimeth- | 3-Methacryloxypropyltrimethoxysilane (17.5) | — | Benzenesulfonic | 3.5 | Not |
| Example | siloxane | oxysilane (47.5) | 3-(3,4-Epoxycyclohexyl)propyltrimethoxysilane (5) | | acid | | performed |
| 5 | (A-5) | Dimethyldimeth- | 3-Trimethoxysilylpropylsuccinic anhydride (10) | | pyridine salt | | |
| | solution | oxysilane (20) | | | (1.0) | | |
| Synthesis | Poly | Diphenyldimeth- | 3-Methacryloxypropyltrimethoxysilane (17.5) | — | Benzenesulfonic | 3.7 | Not |
| Example | siloxane | oxysilane (47.5) | 3-(3,4-Epoxycyclohexyl)propyltrimethoxysilane (5) | | acid | | performed |
| 6 | (A-6) | Dimethyldimeth- | 3-Trimethoxysilylpropylsuccinic anhydride (10) | | aniline salt | | |
| | solution | oxysilane (20) | | | (1.0) | | |
| Synthesis | Poly | Diphenyldimeth- | 3-Methacryloxypropyltrimethoxysilane (17.5) | — | Tetraethyl- | 5.9 | Not |
| Example | siloxane | oxysilane (47.5) | 3-(3,4-Epoxycyclohexyl)propyltrimethoxysilane (5) | | ammonium | | performed |
| 7 | (A-7) | Dimethyldimeth- | 3-Trimethoxysilylpropylsuccinic anhydride (10) | | p-toluenesulfonate | | |
| | solution | oxysilane (20) | | | (1.0) | | |
| Synthesis | Poly | Diphenyldimeth- | Methyltrimethoxysilane (25) | Tetraeth- | p-Toluenesulfonic | 3.6 | Not |
| Example | siloxane | oxysilane (50) | 3-(3,4-Epoxycyclohexyl)propyltrimethoxysilane (10) | oxysilane | acid | | performed |
| 8 | (A-8) | | | (15) | pyridine salt | | |
| | solution | | | | (1.0) | | |

TABLE 2

| | | | | | Condensation catalyst | | |
|---|---|---|---|---|---|---|---|
| | | | | | (wt % with respect to | | |
| | | | | | silane raw material) | | |
| | | Raw material (mol %) | | | | pH | |
| | | Alkoxysilane | | | | value of | |
| | | constituting | | Other | | 1.0 wt % | Catalyst |
| | | general | | alkoxy | Catalyst | aqueous | removal |
| | | formula (4) | Alkoxysilane constituting general formula (5) | silane | species | solution | step |
| Synthesis | Poly | Diphenyl- | 3-Methacryloxypropyltrimethoxysilane (17.5) | — | Phosphoric | 1.5 | Not |
| Example | siloxane | dimethoxysilane | 3-(3,4-Epoxycyclohexyl)propyltrimethoxysilane (5) | | acid | | performed |
| 9 | (A-9) | (47.5) | 3-Trimethoxysilylpropylsuccinic anhydride (10) | | (1.0) | | |
| | solution | Dimethyl- | | | | | |
| | | dimethoxysilane | | | | | |
| | | (20) | | | | | |
| Synthesis | Poly | Diphenyl- | 3-Methacryloxypropyltrimethoxysilane (17.5) | — | Phosphoric | 1.5 | Performed |
| Example | siloxane | dimethoxysilane | 3-(3,4-Epoxycyclohexy1)propyltrimethoxysilane (5) | | acid | | |
| 10 | (A-10) | (47.5) | 3-Trimethoxysilylpropylsuccinic anhydride (10) | | (1.0) | | |
| | solution | Dimethyl- | | | | | |
| | | dimethoxysilane | | | | | |
| | | (20) | | | | | |
| Synthesis | Poly | Diphenyl- | 3-Methacryloxypropyltrimethoxysilane (17.5) | — | p-Toluene- | 3.6 | Not |
| Example | siloxane | dimethoxysilane | 3-(3,4-Epoxycyclohexyl)propyltrimethoxysilane (5) | | sulfonic | | performed |
| 11 | (A-11) | (47.5) | 3-Trimethoxysilylpropylsuccinic anhydride (10) | | acid | | |
| | solution | Dimethyl- | | | pyridine | | |
| | | dimethoxysilane | | | salt | | |
| | | (20) | | | (0.1) | | |
| Synthesis | Poly | Diphenyl- | 3-Methacryloxypropyltrimethoxysilane (17.5) | — | p-Toluene- | 3.6 | Not |
| Example | siloxane | dimethoxysilane | 3-(3,4-Epoxycyclohexyl)propyltrimethoxysilane (5) | | sulfonic | | performed |
| 12 | (A-12) | (47.5) | 3-Trimethoxysilylpropylsuccinic anhydride (10) | | acid | | |
| | solution | Dimethyl- | | | pyridine | | |
| | | dimethoxysilane | | | salt | | |
| | | (20) | | | (3.0) | | |
| Synthesis | Poly | Diphenyl- | 3-Methacryloxypropyltrimethoxysilane (17.5) | — | p-Toluene- | 3.6 | Not |
| Example | siloxane | dimethoxysilane | 3-(3,4-Epoxycyclohexy1)propyltrimethoxysilane (5) | | sulfonic | | performed |
| 13 | (A-13) | (47.5) | 3-Trimethoxysilylpropylsuccinic anhydride (10) | | acid | | |
| | solution | Dimethyl- | | | pyridine | | |
| | | dimethoxysilane | | | salt | | |
| | | (20) | | | (0.01) | | |
| Synthesis | Poly | Diphenyl- | 3-Methacryloxypropyltrimethoxysilane (17.5) | — | p-Toluene- | 3.6 | Not |
| Example | siloxane | dimethoxysilane | 3-(3,4-Epoxycyclohexyl)propyltrimethoxysilane (5) | | sulfonic | | performed |
| 14 | (A-14) | (47.5) | 3-Trimethoxysilylpropylsuccinic anhydride (10) | | acid | | |
| | solution | Dimethyl- | | | pyridine | | |
| | | dimethoxysilane | | | salt | | |
| | | (20) | | | (5.5) | | |

TABLE 3

| | | | | | Condensation catalyst | | |
|---|---|---|---|---|---|---|---|
| | | | | | (wt % with respect to | | |
| | | | | | silane raw material) | | |
| | | Raw material (mol %) | | | | pH | |
| | | Alkoxysilane | | | | value of | |
| | | constituting | | Other | | 1.0 wt % | Catalyst |
| | | general | | alkoxy | Catalyst | aqueous | removal |
| | | formula (4) | Alkoxysilane constituting general formula (5) | silane | species | solution | step |
| Synthesis | Poly | — | 3-Methacryloxypropyltrimethoxysilane (35) | — | p-Toluene- | 3.6 | Not |
| Example | siloxane | | Methyltrimethoxysilane (20) | | sulfonic acid | | performed |
| 15 | (A-15) | | Trifluoropropyltrimethoxysilane (40) | | pyridine salt | | |
| | solution | | 3-Trimethoxysilylpropylsuccinic anhydride (5) | | (1.0) | | |
| Synthesis | Poly | — | 3-Methacryloxypropyltrimethoxysilane (35) | — | Trifluoroacetic | 3.3 | Not |
| Example | siloxane | | Methyltrimethoxysilane (20) | | acid | | performed |
| 16 | (A-16) | | Trifluoropropyltrimethoxysilane (40) | | pyridine salt | | |
| | solution | | 3-Trimethoxysilylpropylsuccinic anhydride (5) | | (1.0) | | |
| Synthesis | Poly | Dimethyldimeth- | 3-Methacryloxypropyltrimethoxysilane (17.5) | — | Methanesulfonic | 3.3 | Not |
| Example | siloxane | oxysilane | 3-(3,4-Epoxycyclohexyl)propyltrimethoxysilane (5) | | acid | | performed |
| 17 | (A-17) | (20) | 3-Trimethoxysilylpropylsuccinic anhydride (10) | | pyridine salt | | |
| | solution | | p-Tolyltrimethoxysilane (47.5) | | (1.0) | | |
| Synthesis | Poly | Dimethyldimeth- | 3-Methacryloxypropyltrimethoxysilane (17.5) | — | Methanesulfonic | 3.3 | Not |
| Example | siloxane | oxysilane | 3-(3,4-Epoxycyclohexyl)propyltrimethoxysilane (5) | | acid | | performed |
| 18 | (A-18) | (20) | 3-Trimethoxysilylpropylsuccinic anhydride (10) | | pyridine salt | | |
| | solution | | 3,5-Dimethylphenyltrimethoxysilane (47.5) | | (1.0) | | |
| Synthesis | Poly | Dimethyldimeth- | 3-Methacryloxypropyltrimethoxysilane (17.5) | — | Methanesulfonic | 3.3 | Not |
| Example | siloxane | oxysilane | 3-(3,4-Epoxycyclohexyl)propyltrimethoxysilane (5) | | acid | | performed |
| 19 | (A-19) | (20) | 3-Trimethoxysilylpropylsuccinic anhydride (10) | | pyridine salt | | |
| | solution | | M-aminophenyltrimethoxysilane (47.5) | | (1.0) | | |
| Synthesis | Poly | Dimethyldimeth- | 3-Methacryloxypropyltrimethoxysilane (17.5) | — | Methanesulfonic | 3.3 | Not |
| Example | siloxane | oxysilane | 3-(3,4-Epoxycyclohexyl)propyltrimethoxysilane (5) | | acid | | performed |
| 20 | (A-20) | (20) | 3-Trimethoxysilylpropylsuccinic anhydride (10) | | pyridine salt | | |
| | solution | | p-Styryltrimethoxysilane (47.5) | | (1.0) | | |
| Synthesis | Poly | Dimethyldimeth- | 3-Methacryloxypropyltrimethoxysilane (17.5) | — | Methanesulfonic | 3.3 | Not |
| Example | siloxane | oxysilane | 3-(3,4-Epoxycyclohexy1)propyltrimethoxysilane (5) | | acid | | performed |
| 21 | (A-21) | (20) | 3-Trimethoxysilylpropylsuccinic anhydride (10) | | pyridine salt | | |
| | solution | | 1-Naphthyltrimethoxysilane (47.5) | | (1.0) | | |

TABLE 4

| | | | | | Condensation catalyst | | |
|---|---|---|---|---|---|---|---|
| | | | | | (wt % with respect to | | |
| | | | | | silane raw material) | | |
| | | Raw material (mol %) | | | | pH | |
| | | Alkoxysilane | | | | value of | |
| | | constituting | | Other | | 1.0 wt % | Catalyst |
| | | general | | alkoxy | Catalyst | aqueous | removal |
| | | formula (4) | Alkoxysilane constituting general formula (5) | silane | species | solution | step |
| Synthesis | Poly | Dimethyldimethoxysilane | 3-Methacryloxypropyltrimethoxysilane (17.5) | — | Phosphoric | 1.5 | Performed |
| Example | siloxane | (20) | 3-(3,4-Epoxycyclohexyl)propyltrimethoxysilane (5) | | acid | | |
| 22 | (A-22) | | 3-Trimethoxysilylpropylsuccinic anhydride (10) | | (1.0) | | |
| | solution | | p-Tolyltrimethoxysilane (47.5) | | | | |
| Synthesis | Poly | Dimethyldimethoxysilane | 3-Methacryloxypropyltrimethoxysilane (17.5) | — | Phosphoric | 1.5 | Performed |
| Example | siloxane | (20) | 3-(3,4-Epoxycyclohexyl)propyltrimethoxysilane (5) | | acid | | |
| 23 | (A-23) | | 3-Trimethoxysilylpropylsuccinic anhydride (10) | | (1.0) | | |
| | solution | | 3,5-Dimethylphenyltrimethoxysilane (47.5) | | | | |
| Synthesis | Poly | Dimethyldimethoxysilane | 3-Methacryloxypropyltrimethoxysilane (17.5) | — | Phosphoric | 1.5 | Performed |
| Example | siloxane | (20) | 3-(3,4-Epoxycyclohexyl)propyltrimethoxysilane (5) | | acid | | |
| 24 | (A-24) | | 3-Trimethoxysilylpropylsuccinic anhydride (10) | | (1.0) | | |
| | solution | | M-aminophenyltrimethoxysilane (47.5) | | | | |
| Synthesis | Poly | Dimethyldimethoxysilane | 3-Methacryloxypropyltrimethoxysilane (17.5) | — | Phosphoric | 1.5 | Performed |
| Example | siloxane | (20) | 3-(3,4-Epoxycyclohexyl)propyltrimethoxysilane (5) | | acid | | |
| 25 | (A-25) | | 3-Trimethoxysilylpropylsuccinic anhydride (10) | | (1.0) | | |
| | solution | | p-Styryltrimethoxysilane (47.5) | | | | |
| Synthesis | Poly | Dimethyldimethoxysilane | 3-Methacryloxypropyltrimethoxysilane (17.5) | — | Phosphoric | 1.5 | Performed |
| Example | siloxane | (20) | 3-(3,4-Epoxycyclohexyl)propyltrimethoxysilane (5) | | acid | | |
| 26 | (A-26) | | 3-Trimethoxysilylpropylsuccinic anhydride (10) | | (1.0) | | |
| | solution | | 1-Naphthyltrimethoxysilane (47.5) | | | | |

### Example 1 Siloxane Resin Composition for Forming Cured Film (P-1)

Under a yellow light, 65.7 g of the polysiloxane (A-1) solution containing p-toluenesulfonic acid pyridine salt as the organic salt, 0.750 g of 1,2-octanedione, 1-[4-(phenylthio)phenyl]-,2-(o-benzoyloxime) (“IRGACURE” (registered trademark) OXE-01, manufactured BASF Japan Ltd. (hereinafter, “OXE-01”)) as the photosensitizer (photopolymerization initiator), 0.250 g of bis(2,4,6-trimethylbenzoyl)-phenylphosphine oxide (“IRGACURE” 819, manufactured BASF Japan Ltd. (hereinafter, “IC-819”)), 15.0 g of dipentaerythritol hexaacrylate (“KAYARAD” (registered trademark) DPHA, manufactured by Shin Nippon Yakugyo Co., Ltd. (hereinafter, “DPHA”)) as the photopolymerizable compound, 0.150 g of ethylenebis(oxyethylene)bis[3-(5-tert-butyl-4-hydroxy-m-tolyl)propionate] (“IRGANOX” (registered trademark) 1010, manufactured BASF Japan Ltd. (hereinafter, “IRGANOX 1010”)) as the additive, 1.00 g of 3-acryloxypropyltrimethoxysilane (KBM-5103, manufactured by Shin-Etsu Chemical Co., Ltd. (hereinafter, “KBM-5103”)), and 0.300 g (corresponding to a concentration of 300 ppm) of a 10% by mass diluted solution of PGMEA of an acrylic surfactant (“BYK” (registered trademark) 352, manufactured by BYK Japan KK (hereinafter, “BYK-352”)) were dissolved in a solvent of 6.90 g of PGMEA and 10.0 g of DAA, followed by stirring at room temperature. The obtained mixture was filtered through a 0.45 μm filter to obtain a siloxane resin composition for forming a cured film (P-1).

### Examples 2 to 6 Siloxane Resin Compositions for Forming Cured Film (P-2) to (P-6)

Siloxane resin compositions for forming a cured film (P-2) to (P-6) were obtained in the same manner as in Example 1, except that the polysiloxane (A-1) solution was changed to the polysiloxane (A-2) solution to the polysiloxane (A-6) solution, respectively.

### Example 7 Siloxane Resin Composition for Forming Cured Film (P-7)

Under a yellow light, 92.9 g of the polysiloxane (A-8) solution containing p-toluenesulfonic acid pyridine salt as the organic salt, 2.50 g of THP-17 (trade name, manufactured by Toyo Gosei Co., Ltd.) as the photosensitizer (quinone diazide compound), 1.00 g of 2-(3,4-epoxycyclohexyl)ethyltrimethoxysilane (KBM-303, manufactured by Shin-Etsu Chemical Co., Ltd. (hereinafter, “KBM-303”)), and 0.300 g (corresponding to a concentration of 300 ppm) of a 10% by mass diluted solution of PGMEA of an acrylic surfactant (“BYK” (registered trademark) 352, manufactured by BYK Japan KK (hereinafter, “BYK-352”)) were dissolved in a solvent of 0.258 g of PGMEA and 3.00 g of DAA, followed by stirring at room temperature. The obtained mixture was filtered through a 0.45 μm filter to obtain a siloxane resin composition for forming a cured film (P-7).

### Example 8 Siloxane Resin Composition for Forming Cured Film (P-8)

A siloxane resin composition for forming a cured film (P-8) was obtained in the same manner as in Example 1, except that the polysiloxane (A-1) solution was changed to the polysiloxane (A-10) solution and 0.657 g of p-toluenesulfonic acid pyridine salt was added as the organic salt.

### Examples 9 to 12 Siloxane Resin Compositions for Forming Cured Film (P-9) to (P-12)

Siloxane resin compositions for forming a cured film (P-9) to (P-12) were obtained in the same manner as in Example 1, except that the polysiloxane (A-1) solution was changed to the polysiloxane (A-11) solution to the polysiloxane (A-14) solution, respectively.

### Examples 13 to 19 Siloxane Resin Compositions for Forming Cured Film (P-13) to (P-19)

Siloxane resin compositions for forming a cured film (P-13) to (P-19) were obtained in the same manner as in Example 1, except that the polysiloxane (A-1) solution was changed to the polysiloxane (A-15) solution to the polysiloxane (A-21) solution, respectively.

### Example 20 Resin Composition for Partition (P-20)

After 50.0 g of titanium dioxide white pigment (CR-97; manufactured by ISHIHARA SANGYO KAISHA, LTD. (hereinafter, “CR-97”)) was mixed with 50.0 g of the polysiloxane (A-1) solution obtained in Synthesis Example 1, the resulting mixture was dispersed with use of a mill-type disperser loaded with zirconia beads to obtain a pigment dispersion (MW-1). Next, under a yellow light, 40.25 g of the pigment dispersion (MW-1), 15.70 g of the polysiloxane (A-1) solution containing p-toluenesulfonic acid pyridine salt as the organic salt, 0.755 g of OXE-01 as the photosensitizer (photopolymerization initiator), 0.252 g of IC-819, 15.1 g of DPHA as the photopolymerizable compound, 0.151 g of IRGANOX 1010 as the additive, 1.01 g of KBM-5103, and 0.302 g (corresponding to a concentration of 300 ppm) of a 10% by mass diluted solution of PGMEA of an acrylic surfactant BYK-352 were dissolved in a solvent of 17.02 g of PGMEA and 10.1 g of DAA, followed by stirring at room temperature. The obtained mixture was filtered through a 5.0 μm filter to obtain a siloxane resin composition for forming a cured film (P-20).

### Example 21 Resin Composition for Partition (P-21)

After 50.0 g of titanium dioxide white pigment CR-97 was mixed with 50.0 g of the polysiloxane (A-2) solution obtained in Synthesis Example 2, the resulting mixture was dispersed with use of a mill-type disperser loaded with zirconia beads to obtain a pigment dispersion (MW-2). A siloxane resin composition for forming a cured film (P-21) was obtained in the same manner as in Example 20, except that 40.25 g of the pigment dispersion (MW-1) was added instead of the pigment dispersion MW-1, and 15.70 g of the polysiloxane (A-2) solution containing methanesulfonic acid pyridine salt was added instead of the polysiloxane (A-1) solution.

### Comparative Example 1 Siloxane Resin Composition for Forming Cured Film (P-22)

A siloxane resin composition for forming a cured film (P-22) was obtained in the same manner as in Example 1, except that the polysiloxane (A-1) solution was changed to the polysiloxane (A-7) solution.

### Comparative Example 2 Siloxane Resin Composition for Forming Cured Film (P-23)

A siloxane resin composition for forming a cured film (P-23) was obtained in the same manner as in Example 1, except that the polysiloxane (A-1) solution was changed to the polysiloxane (A-9) solution containing phosphoric acid.

### Comparative Example 3 Siloxane Resin Composition for Forming Cured Film (P-24)

A siloxane resin composition for forming a cured film (P-24) was obtained in the same manner as in Example 1, except that the polysiloxane (A-1) solution was changed to the polysiloxane (A-10) solution.

### Comparative Example 4 Siloxane Resin Composition for Forming Cured Film (P-25)

With reference to Japanese Patent No. 645892, under a yellow light, a PGMEA solution having a concentration of 20% by mass of a reactant obtained by previously reacting a phosphoric acid derivative compound, 2-methacryloyloxyethyl acid phosphate (trade name “P-1M” manufactured by Kyoeisha Chemical Co., Ltd.) with monoethanolamine at a mass ratio of 9.5:0.5 was prepared. This solution (2.47 g), 65.0 g of the polysiloxane (A-1) solution, 0.742 g of OXE-01 as the photosensitizer (photopolymerization initiator), 0.247 g of IC-819, 14.8 g of DPHA as the photopolymerizable compound, 0.148 g of IRGANOX 1010 as the additive, 0.990 g of KBM-5103, and 0.300 g (corresponding to a concentration of 300 ppm) of a 10% by mass diluted solution of PGMEA of BYK-352 were dissolved in a solvent of 5.25 g of PGMEA and 10.0 g of DAA, followed by stirring at room temperature. The obtained mixture was filtered through a 0.45 μm filter to obtain a siloxane resin composition for forming a cured film (P-25).

### Comparative Examples 5 to 9 Siloxane Resin Compositions for Forming Cured Film (P-26) to (P-30)

Siloxane resin compositions for forming a cured film (P-26) to (P-30) were obtained in the same manner as in Comparative Example 3, except that the polysiloxane (A-10) solution was changed to the polysiloxane (A-22) solution to the polysiloxane (A-26) solution, respectively.

The compositions employed in Examples 1 to 21 and Comparative Examples 1 to 9 are shown in Tables 5 to 7.

TABLE 5

| | | | | (b) Organic salt | | | | | | | | |
|---|---|---|---|---|---|---|---|---|---|---|---|---|
| | | | | (wt % with respect to (a) polysiloxane) | | | | | | | | |
| | | | | | pH value of | | | | | | | |
| | | (a) | | | 1.0 wt % | (c) | | (d) | | | | |
| | Resin | Polysiloxane | | | aqueous | Solvent | | Photosensitizer | | Additive | | Others |
| | composition | (wt %) | | Type | solution | (wt %) | | (wt %) | | (wt %) | | (wt %) |
| Example 1 | P-1 | A-1 | (32.5) | p-Toluenesulfonic acid | 3.6 | PGMEA | (40) | OXE-01 | (0.8) | DPHA | (15) | — |
| | | | | pyridine salt (1.0) | | DAA | (10) | IC-819 | (0.3) | Irganox1010 | (0.2) | |
| | | | | | | | | | | KBM-5103 | (1.0) | |
| Example 2 | P-2 | A-2 | (32.5) | Methanesulfonic acid | 3.3 | PGMEA | (40) | OXE-01 | (0.8) | DPHA | (15) | — |
| | | | | pyridine salt (1.0) | | DAA | (10) | IC-819 | (0.3) | Irganox1010 | (0.2) | |
| | | | | | | | | | | KBM-5103 | (1.0) | |
| Example 3 | P-3 | A-3 | (32.5) | Trifluoromethanesulfonic | 3.5 | PGMEA | (40) | OXE-01 | (0.8) | DPHA | (15) | — |
| | | | | acid pyridine salt (1.0) | | DAA | (10) | IC-819 | (0.3) | Irganox1010 | (0.2) | |
| | | | | | | | | | | KBM-5103 | (1.0) | |
| Example 4 | P-4 | A-4 | (32.5) | Trifluoroacetic acid | 3.3 | PGMEA | (40) | OXE-01 | (0.8) | DPHA | (15) | — |
| | | | | pyridine salt (1.0) | | DAA | (10) | IC-819 | (0.3) | Irganox1010 | (0.2) | |
| | | | | | | | | | | KBM-5103 | (1.0) | |
| Example 5 | P-5 | A-5 | (32.5) | Benzenesulfonic | 3.5 | PGMEA | (40) | OXE-01 | (0.8) | DPHA | (15) | — |
| | | | | acid pyridine salt (1.0) | | DAA | (10) | IC-819 | (0.3) | Irganox1010 | (0.2) | |
| | | | | | | | | | | KBM-5103 | (1.0) | |
| Example 6 | P-6 | A-6 | (32.5) | Benzenesulfonic | 3.7 | PGMEA | (40) | OXE-01 | (0.8) | DPHA | (15) | — |
| | | | | acid aniline salt (1.0) | | DAA | (10) | IC-819 | (0.3) | Irganox1010 | (0.2) | |
| | | | | | | | | | | KBM-5103 | (1.0) | |
| Example 7 | P-7 | A-8 | (46.0) | p-Toluenesulfonic | 3.6 | PGMEA | (47) | THP-17 | (2.5) | KBM-303 | (1.0) | — |
| | | | | acid pyridine salt (1.0) | | DAA | (3) | | | | | |
| Example 8 | P-8 | A-10 | (32.5) | p-Toluenesulfonic | 3.6 | PGMEA | (40) | OXE-01 | (0.8) | DPHA | (15) | — |
| | | | | acid pyridine salt (1.0) | | DAA | (10) | IC-819 | (0.3) | Irganox1010 | (0.2) | |
| | | | | | | | | | | KBM-5103 | (1.0) | |
| Example 9 | P-9 | A-11 | (32.8) | p-Toluenesulfonic | 3.6 | PGMEA | (40) | OXE-01 | (0.8) | DPHA | (15) | — |
| | | | | acid pyridine salt (0.1) | | DAA | (10) | IC-819 | (0.3) | Irganox1010 | (0.2) | |
| | | | | | | | | | | KBM-5103 | (1.0) | |
| Example | P-10 | A-12 | (31.9) | p-Toluenesulfonic | 3.6 | PGMEA | (40) | OXE-01 | (0.8) | DPHA | (15) | — |
| 10 | | | | acid pyridine salt (3.0) | | DAA | (10) | IC-819 | (0.3) | Irganox1010 | (0.2) | |
| | | | | | | | | | | KBM-5103 | (1.0) | |
| Example | P-11 | A-13 | (32.8) | p-Toluenesulfonic | 3.6 | PGMEA | (40) | OXE-01 | (0.8) | DPHA | (15) | — |
| 11 | | | | acid pyridine salt (0.01) | | DAA | (10) | IC-819 | (0.3) | Irganox1010 | (0.2) | |
| | | | | | | | | | | KBM-5103 | (1.0) | |
| Example | P-12 | A-14 | (31.0) | p-Toluenesulfonic | 3.6 | PGMEA | (40) | OXE-01 | (0.8) | DPHA | (15) | — |
| 12 | | | | acid pyridine salt (5.5) | | DAA | (10) | IC-819 | (0.3) | Irganox1010 | (0.2) | |
| | | | | | | | | | | KBM-5103 | (1.0) | |

TABLE 6

| | | | | (b) Organic salt | | | | | | | | | |
|---|---|---|---|---|---|---|---|---|---|---|---|---|---|
| | | | | (wt % with respect to | | | | | | | | | |
| | | | | (a) polysiloxane) | | | | | | | | | |
| | | | | | pH | | | | | | | | |
| | | | | | value of | | | | | | | | |
| | Resin | (a) | | | 1.0 wt % | (c) | | (d) | | | | | |
| | compo- | Polysiloxane | | | aqueous | Solvent | | Photosensitizer | | Additive | | Others | |
| | sition | (wt %) | | Type | solution | (wt %) | | (wt %) | | (wt %) | | (wt %) | |
| Example | P-13 | A-15 | (32.5) | p-Toluenesulfonic | 3.6 | PGMEA | (40) | OXE-01 | (0.8) | DPHA | (15) | — | |
| 13 | | | | acid pyridine | | DAA | (10) | IC-819 | (0.3) | Irganox 1010 | (0.2) | | |
| | | | | salt (1.0) | | | | | | KBM-5103 | (1.0) | | |
| Example | P-14 | A-16 | (32.5) | Trifluoroacetic | 3.3 | PGMEA | (40) | OXE-01 | (0.8) | DPHA | (15) | — | |
| 14 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-15 | A-17 | (32.5) | Methanesulfonic | 3.3 | PGMEA | (40) | OXE-01 | (0.8) | DPHA | (15) | — | |
| 15 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-16 | A-18 | (32.5) | Methanesulfonic | 3.3 | PGMEA | (40) | OXE-01 | (0.8) | DPHA | (15) | — | |
| 16 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-17 | A-19 | (32.5) | Methanesulfonic | 3.3 | PGMEA | (40) | OXE-01 | (0.8) | DPHA | (15) | — | |
| 17 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-18 | A-20 | (32.5) | Methanesulfonic | 3.3 | PGMEA | (40) | OXE-01 | (0.8) | DPHA | (15) | — | |
| 18 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-19 | A-21 | (32.5) | Methanesulfonic | 3.3 | PGMEA | (47) | THP-17 | (2.5) | KBM-303 | (1.0) | — | |
| 19 | | | | acid pyridine salt (1.0) | | DAA | (3) | | | | | | |
| Example | P-20 | A-1 | (12.8) | p-Toluenesulfonic | 3.6 | PGMEA | (40) | OXE-01 | (0.8) | DPHA | (15) | CR-97 | (20) |
| 20 | | | | acid pyridine salt (1.0) | | DAA | (10) | IC-819 | (0.3) | Irganox 1010 | (0.2) | | |
| | | | | | | | | | | KBM-5103 | (1.0) | | |
| Example | P-21 | A-2 | (12.8) | Methanesulfonic | 3.3 | PGMEA | (40) | OXE-01 | (0.8) | DPHA | (15) | CR-97 | (20) |

| | | | | | | | |
|---|---|---|---|---|---|---|---|
| 21 | acid pyridine salt (1.0) | DAA | (10) | IC-819 | (0.3) | Irganox 1010 | (0.2) |
| | | | | | | KBM-5103 | (1.0) |

TABLE 7

| | | | | (b) Organic salt | | | | | | | | |
|---|---|---|---|---|---|---|---|---|---|---|---|---|
| | | | | (wt % with respect to | | | | | | | | |
| | | | | (a) polysiloxane) | | | | | | | | |
| | | | | | pH | | | | | | | |
| | | | | | value of | | | | | | | |
| | | (a) | | | 1.0 wt % | | | (d) | | | | |
| | Resin | Polysiloxane | | | aqueous | (c) Solvent | | Photosensitizer | | Additive | | Others |
| | composition | (wt %) | | Type | solution | (wt %) | | (wt %) | | (wt %) | | (wt %) |
| Comparative | P-22 | A-7 | (32.5) | Tetraethylammonium | 5.9 | PGMEA | (40) | OXE-01 | (0.8) | DPHA | (15) | — |
| Example 1 | | | | p-toluenesulfonate | | DAA | (10) | IC-819 | (0.3) | Irganox1010 | (0.2) | |
| | | | | (1.0) | | | | | | KBM-5103 | (1.0) | |
| Comparative | P-23 | A-9 | (32.5) | — | — | PGMEA | (40) | OXE-01 | (0.8) | DPHA | (15) | Phosphoric |
| Example 2 | | | | | | DAA | (10) | IC-819 | (0.3) | Irganox1010 | (0.2) | acid |
| | | | | | | | | | | KBM-5103 | (1.0) | (0.4) |
| Comparative | P-24 | A-10 | (33.5) | — | — | PGMEA | (40) | OXE-01 | (0.8) | DPHA | (15) | |
| Example 3 | | | | | | DAA | (10) | IC-819 | (0.3) | Irganox1010 | (0.2) | — |
| | | | | | | | | | | KBM-5103 | (1.0) | |
| Comparative | P-25 | A-10 | (32.5) | P1-M:monoethan- | 2.5 | PGMEA | (40) | OXE-01 | (0.8) | DPHA | (15) | — |
| Example 4 | | | | olamine = 9.5:0.5 | | DAA | (10) | IC-819 | (0.3) | Irganox1010 | (0.2) | |
| | | | | (1.0) | | | | | | KBM-5103 | (1.0) | |
| Comparative | P-26 | A-22 | (33.5) | — | — | PGMEA | (40) | OXE-01 | (0.8) | DPHA | (15) | — |
| Example 5 | | | | | | DAA | (10) | IC-819 | (0.3) | Irganox1010 | (0.2) | |
| | | | | | | | | | | KBM-5103 | (1.0) | |
| Comparative | P-27 | A-23 | (33.5) | — | — | PGMEA | (40) | OXE-01 | (0.8) | DPHA | (15) | — |
| Example 6 | | | | | | DAA | (10) | IC-819 | (0.3) | Irganox1010 | (0.2) | |
| | | | | | | | | | | KBM-5103 | (1.0) | |
| Comparative | P-28 | A-24 | (33.5) | — | — | PGMEA | (40) | OXE-01 | (0.8) | DPHA( | 15) | — |
| Example 7 | | | | | | DAA | (10) | IC-819 | (0.3) | Irganox1010 | (0.2) | |
| | | | | | | | | | | KBM-5103 | (1.0) | |
| Comparative | P-29 | A-25 | (33.5) | — | — | PGMEA | (40) | OXE-01 | (0.8) | DPHA | (15) | — |
| Example 8 | | | | | | DAA | (10) | IC-819 | (0.3) | Irganox1010 | (0.2) | |
| | | | | | | | | | | KBM-5103 | (1.0) | |
| Comparative | P-30 | A-26 | (33.5) | — | — | PGMEA | (40) | OXE-01 | (0.8) | DPHA | (15) | — |
| Example 9 | | | | | | DAA | (10) | IC-819 | (0.3) | Irganox1010 | (0.2) | |
| | | | | | | | | | | KBM-5103 | (1.0) | |

Evaluation methods in the Examples 22 to 42 and Comparative Examples 10 to 18 are described below.

### Storage Stability

The viscosity (viscosity before storage) of the siloxane resin composition for forming a cured film obtained in each of Examples and Comparative Examples was measured after the preparation was completed. The viscosity was measured at 23° C. using an E-type rotary viscometer (VISCOMETER TV-25 (manufactured by Toki Sangyo Co., Ltd.)). The siloxane resin composition for forming a cured film obtained in each of Examples and Comparative Examples was placed in a sealed container, and the viscosity after storage at room temperature (23° C.) for 7 days and the viscosity after at room temperature (40° C.) for 3 days were measured in the same manner. The storage stability was evaluated from the viscosity change rate ({|viscosity after storage−viscosity before storage|/viscosity before storage}×100) according to the following criteria for each storage condition.
A: Viscosity change rate of less than 5%
B: Viscosity change rate of of 5% or more and less than 10%
C: Viscosity change rate of 10% or more

### Patternability

The siloxane resin composition for forming a cured film obtained in each of Examples and Comparative Examples was spin-coated on a bare glass substrate using a spin coater (trade name: 1H-360S, manufactured by MIKASA CO., LTD.), and the substrate was prebaked on a hot plate (trade name: SCW-636, manufactured by Dainippon Screen Mfg. Co., Ltd.) at 100° C. for 2 minutes to produce a film having a film thickness of 10 μm.

The produced film was exposed using a parallel light mask aligner (trade name: PLA-501F, manufactured by Canon Inc.) through a gray scale mask having each of line-and-space patterns having widths of 100 μm, 50 μm, 40 μm, 30 μm, 20 μm, and 10 μm using an ultra-high-pressure mercury lamp as a light source at an exposure amount of 100 mJ/cm² at a gap of 100 μm. Thereafter, the exposed film was shower-developed with a 2.38% by mass TMAH for 60 seconds using an automatic developing apparatus (“AD-1200 (trade name)” manufactured by MIKASA CO., LTD.), and then rinsed with water for 30 seconds.

The minimum pattern dimension after exposure and development was taken as the resolution. The pattern after development was observed with a microscope with a magnification adjusted to 50 to 100 times, and the development residue was evaluated according to the following criteria based on the degree of the unexposed portion remaining undissolved.
A: No residue is observed in a pattern of 50 μm or less.
B: No residue is observed in a pattern of more than 50 μm, but a residue is observed in a pattern of 50 μm or less.
C: A residue is observed in a pattern of more than 50 μm.

### Solvent Resistance

The siloxane resin composition for forming a cured film obtained in each of Examples and Comparative Examples was spin-coated on a bare glass substrate using a spin coater (trade name: 1H-360S, manufactured by MIKASA CO., LTD.), and the substrate was prebaked on a hot plate (trade name: SCW-636, manufactured by Dainippon Screen Mfg. Co., Ltd.) at 100° C. for 2 minutes to produce a film having a film thickness of 11 μm.

The produced film was exposed using a parallel light mask aligner (trade name: PLA-501F, manufactured by Canon Inc.) and using an ultra-high-pressure mercury lamp as a light source at an exposure amount of 100 mJ/cm². Thereafter, the exposed film was shower-developed with a 2.38% by mass TMAH for 60 seconds using an automatic developing apparatus (“AD-1200 (trade name)” manufactured by MIKASA CO., LTD.), and then rinsed with water for 30 seconds. The exposed film was cured at 180° C. for 1 hour in air using an oven (trade name: IHPS-222, manufactured by Espec Corp.) to produce a cured film having a film thickness of 10 μm.

TOK106 (manufactured by TOKYO OHKA KOGYO CO., LTD.) as a resist stripping solution was selected as a solvent for a solvent resistance test, and the cured film was immersed therein at 70° C. for 5 minutes to perform a solvent resistance test. The film thickness before and after the solvent resistance test was measured, and the solvent resistance was evaluated according to the following criteria from the film thickness change rate ({|film thickness after solvent resistance test−film thickness before solvent resistance test|/film thickness before solvent resistance test}×100).
A: Film thickness change rate of less than 1%
B: Film thickness change rate of 1% or more and less than 5%
C: Film thickness change rate of 5% or more

### Transmittivity

A cured film was produced using the siloxane resin composition for forming a cured film obtained in each of Examples and Comparative Examples in the same manner as in the evaluation of Substrate adhesion. For the glass substrate having the obtained cured film, the transmittance of ultraviolet light and visible light (300 nm to 800 nm) was measured using the glass substrate used as a reference by a spectrophotometer (U-4100 (manufactured by Hitachi High-Tech Science Corporation)). From the transmittance value at a wavelength of 400 nm, the transmittivity of the cured film was evaluated according to the following criteria.
A: Transmittance of 90% or more
B: Transmittance of less than 90%

### Refractive Index

A cured film having a thickness of 2 μm was produced on each silicon wafer using the siloxane resin composition for forming a cured film obtained in each of Examples and Comparative Examples in the same manner as in the evaluation of Substrate adhesion. The refractive index was measured by irradiating the silicon wafer having the obtained cured film with light having a wavelength of 550 nm from a direction perpendicular to the surface of the cured film under atmospheric pressure at 20° C. using a prism coupler (PC-2000 (manufactured by Metricon Corporation)), and the refractive index was rounded off to three decimal place. In Examples 41 and 42, since the cured film was white and reflected the irradiated light, the measurement could not be performed, which was described as “-” in Table 8-1.

### b* Value

A cured film was produced using the siloxane resin composition for forming a cured film obtained in each of Examples and Comparative Examples in the same manner as in the evaluation of Substrate adhesion. For the glass substrate having the obtained cured film, chromaticity (b* value) was measured in SCI mode from the cured film side using a spectrophotometer (trade name: CM-2600d, manufactured by Konica Minolta, Inc.). The larger the b* value, the larger the yellowness of the cured film.

### SEM-EDX Measurement

A cured film was produced using the siloxane resin composition for forming a cured film obtained in each of Examples and Comparative Examples in the same manner as in the evaluation of Substrate adhesion, except that the curing temperature was changed to 150° C. The ACTIVE: 1608021288.1 obtained cured film was observed with a scanning analytical electron microscope and subjected to EDX analysis at an acceleration voltage of 15 kV. Semiquantitative calculation was performed by ZAF correction calculation, and N (mol %)/Si (mol %) as the atomicity ratio of N to Si, S (mol %)/Si (mol %) as the atomicity ratio of S to Si, P (mol %)/Si (mol %) as the atomicity ratio of P to Si, and F (mol %)/Si (mol %) as the atomicity ratio of F to Si were calculated.

### Impurity Analysis

For the siloxane resin composition for forming a cured film obtained in each of Examples and Comparative Examples, the contents of benzene, toluene, xylene, aniline, styrene, and naphthalene in the resin composition were analyzed and quantified by gas chromatography/mass spectrometry (GC/MS). Regarding the pretreatment method, benzene, toluene, xylene, and styrene were analyzed in accordance with the EPA 5021 A method designated by the U.S. Environmental Protection Agency (EPA). In the analysis of aniline, a method in accordance with European General Test EN 14362-1 was performed. In the analysis of naphthalene, a method in accordance with AfPS GS 2019:01 PAK from German Federal Institute for Risk Assessment was performed. The detected values were summarized in Tables 8-2 and 9-2. When the detection limit (1 ppm) or less was described as “<1”.

Evaluation results of examples and comparative examples are shown in Tables 8 and 9.

TABLE 8-1

| | Resin | Storage stability | | Patternability | | | | | | | | | |
|---|---|---|---|---|---|---|---|---|---|---|---|---|---|
| | compo- | Room | | Resolution | Development | Solvent | | Refractive | b* | SEM-EDX measurement | | | |
| | sition | temperature | 40° C. | (μm) | residue | resistance | Transmittivity | index | value | N/Si | S/Si | P/Si | F/Si |
| Example 22 | P-1 | A | A | 20 | A | A | A | 1.54 | 0.4 | 0.050 | 0.050 | 0.002 | 0 |
| Example 23 | P-2 | A | A | 20 | A | A | A | 1.54 | −0.4 | 0.050 | 0.050 | 0.002 | 0 |
| Example 24 | P-3 | A | A | 20 | A | A | A | 1.52 | 0.6 | 0.050 | 0.050 | 0.002 | 0.150 |
| Example 25 | P-4 | A | A | 20 | A | A | A | 1.52 | 0.6 | 0.050 | 0 | 0.002 | 0.150 |
| Example 26 | P-5 | A | A | 20 | A | A | A | 1.54 | 0.5 | 0.050 | 0.050 | 0.002 | 0 |
| Example 27 | P-6 | A | A | 30 | A | A | B | 1.54 | 2.5 | 0.050 | 0.050 | 0.002 | 0 |
| Example 28 | P-7 | A | A | 10 | A | A | A | 1.52 | 0.2 | 0.050 | 0.050 | 0 | 0 |
| Example 29 | P-8 | A | A | 20 | A | A | A | 1.54 | 0.4 | 0.050 | 0.050 | 0.002 | 0 |
| Example 30 | P-9 | A | A | 20 | A | B | A | 1.54 | 0.1 | 0.004 | 0.004 | 0.002 | 0 |
| Example 31 | P-10 | A | B | 30 | A | A | B | 1.54 | 0.9 | 0.140 | 0.140 | 0.002 | 0 |
| Example 32 | P-11 | A | A | 20 | A | B | A | 1.54 | 0.1 | 0.001 | 0.001 | 0.002 | 0 |
| Example 33 | P-12 | B | B | 40 | B | A | B | 1.54 | 1.5 | 0.250 | 0.250 | 0.002 | 0 |
| Example 34 | P-13 | A | A | 20 | A | A | A | 1.47 | 0.3 | 0.050 | 0.050 | 0.002 | 0 |
| Example 35 | P-14 | A | A | 20 | A | A | A | 1.45 | 0.4 | 0.050 | 0 | 0.002 | 0.150 |
| Example 36 | P-15 | A | A | 20 | A | A | A | 1.51 | 0.1 | 0.050 | 0.050 | 0.002 | 0 |
| Example 37 | P-16 | A | A | 20 | A | A | A | 1.51 | 0.1 | 0.050 | 0.050 | 0.002 | 0 |
| Example 38 | P-17 | B | B | 40 | B | A | B | 1.51 | 1.5 | 0.050 | 0.050 | 0.002 | 0 |
| Example 39 | P-18 | A | A | 20 | A | A | A | 1.50 | 0.1 | 0.050 | 0.050 | 0.002 | 0 |
| Example 40 | P-19 | A | A | 30 | A | A | A | 1.57 | 0.5 | 0.050 | 0.050 | 0.002 | 0 |
| Example 41 | P-20 | A | A | 30 | A | A | B | — | 2.5 | 0.050 | 0.050 | 0.002 | 0 |
| Example 42 | P-21 | A | A | 30 | A | A | B | — | 0.5 | 0.050 | 0.050 | 0.002 | 0 |

TABLE 8-2

| | Resin | Impurity analysis (ppm) | | | | | |
|---|---|---|---|---|---|---|---|
| | composition | Benzene | Toluene | Xylene | Aniline | Styrene | Naphthalene |
| Example 22 | P-1 | <1 | <1 | <1 | <1 | <1 | <1 |
| Example 23 | P-2 | <1 | <1 | <1 | <1 | <1 | <1 |
| Example 24 | P-3 | <1 | <1 | <1 | <1 | <1 | <1 |
| Example 25 | P-4 | <1 | <1 | <1 | <1 | <1 | <1 |
| Example 26 | P-5 | <1 | <1 | <1 | <1 | <1 | <1 |
| Example 27 | P-6 | <1 | <1 | <1 | <1 | <1 | <1 |
| Example 28 | P-7 | <1 | <1 | <1 | <1 | <1 | <1 |
| Example 29 | P-8 | 15 | <1 | <1 | <1 | <1 | <1 |
| Example 30 | P-9 | <1 | <1 | <1 | <1 | <1 | <1 |
| Example 31 | P-10 | <1 | <1 | <1 | <1 | <1 | <1 |
| Example 32 | P-11 | <1 | <1 | <1 | <1 | <1 | <1 |
| Example 33 | P-12 | <1 | <1 | <1 | <1 | <1 | <1 |
| Example 34 | P-13 | <1 | <1 | <1 | <1 | <1 | <1 |
| Example 35 | P-14 | <1 | <1 | <1 | <1 | <1 | <1 |
| Example 36 | P-15 | <1 | <1 | <1 | <1 | <1 | <1 |
| Example 37 | P-16 | <1 | <1 | <1 | <1 | <1 | <1 |
| Example 38 | P-17 | <1 | <1 | <1 | <1 | <1 | <1 |
| Example 39 | P-18 | <1 | <1 | <1 | <1 | <1 | <1 |
| Example 40 | P-19 | <1 | <1 | <1 | <1 | <1 | <1 |
| Example 41 | P-20 | <1 | <1 | <1 | <1 | <1 | <1 |
| Example 42 | P-21 | <1 | <1 | <1 | <1 | <1 | <1 |

TABLE 9-1

| | Resin | Storage stability | | Patternability | | | | | | | | | |
|---|---|---|---|---|---|---|---|---|---|---|---|---|---|
| | compo- | Room | | Resolution | Development | Solvent | | Refractive | b* | SEM-EDX measurement | | | |
| | sition | temperature | 40° C. | (μm) | residue | resistance | Transmittivity | index | value | N/Si | S/Si | P/Si | F/Si |
| Comparative | P-22 | A | A | 30 | A | C | A | 1.54 | 0.4 | 0.050 | 0 | 0 | 0 |
| Example 10 | | | | | | | | | | | | | |
| Comparative | P-23 | C | C | 100 | C | A | A | 1.54 | 0.4 | 0 | 0 | 0.050 | 0 |
| Example 11 | | | | | | | | | | | | | |
| Comparative | P-24 | A | A | 20 | A | C | A | 1.54 | 0.4 | 0 | 0 | 0 | 0 |
| Example 12 | | | | | | | | | | | | | |
| Comparative | P-25 | A | C | 20 | A | A | A | 1.54 | 0.4 | 0.050 | 0 | 0.050 | 0 |
| Example 13 | | | | | | | | | | | | | |
| Comparative | P-26 | A | A | 20 | A | A | A | 1.51 | 0.1 | 0.050 | 0.050 | 0.002 | 0 |
| Example 14 | | | | | | | | | | | | | |
| Comparative | P-27 | A | A | 20 | A | A | A | 1.51 | 0.1 | 0.050 | 0.050 | 0.002 | 0 |
| Example 15 | | | | | | | | | | | | | |
| Comparative | P-28 | B | B | 40 | B | A | B | 1.51 | 1.5 | 0.050 | 0.050 | 0.002 | 0 |
| Example 16 | | | | | | | | | | | | | |
| Comparative | P-29 | A | A | 20 | A | A | A | 1.50 | 0.1 | 0.050 | 0.050 | 0.002 | 0 |
| Example 17 | | | | | | | | | | | | | |
| Comparative | P-30 | A | A | 30 | A | A | A | 1.57 | 0.5 | 0.050 | 0.050 | 0.002 | 0 |
| Example 18 | | | | | | | | | | | | | |

TABLE 9-2

| | Resin | Impurity analysis | | | | | |
|---|---|---|---|---|---|---|---|
| | composition | Benzene | Toluene | Xylene | Aniline | Styrene | Naphthalene |
| Comparative | P-22 | <1 | <1 | <1 | <1 | <1 | <1 |
| Example 10 | | | | | | | |
| Comparative | P-23 | 12 | <1 | <1 | <1 | <1 | <1 |
| Example 11 | | | | | | | |
| Comparative | P-24 | 15 | <1 | <1 | <1 | <1 | <1 |
| Example 12 | | | | | | | |
| Comparative | P-25 | 3 | <1 | <1 | <1 | <1 | <1 |
| Example 13 | | | | | | | |
| Comparative | P-26 | <1 | 10 | <1 | <1 | <1 | <1 |
| Example 14 | | | | | | | |
| Comparative | P-27 | <1 | <1 | 12 | <1 | <1 | <1 |
| Example 15 | | | | | | | |
| Comparative | P-28 | <1 | <1 | <1 | 8 | <1 | <1 |
| Example 16 | | | | | | | |
| Comparative | P-29 | <1 | <1 | <1 | <1 | 5 | <1 |
| Example 17 | | | | | | | |
| Comparative | P-30 | <1 | <1 | <1 | <1 | <1 | 15 |
| Example 18 | | | | | | | |

1.-13. (canceled)

14. A siloxane resin composition for forming a cured film, the siloxane resin composition comprising:
(a) a polysiloxane;
(b) an organic salt;
(c) a solvent; and
(d) a photosensitizer,
wherein a pH value in a 1.0% by mass aqueous solution of the (b) organic salt is 3.0 to 5.5, and
the (d) photosensitizer is a photopolymerization initiator or a quinone diazide compound.

15. The siloxane resin composition for forming a cured film according to claim 14, wherein a content of the (b) organic salt is 0.01 to 5.00 parts by mass based on 100 parts by mass of the (a) polysiloxane.

16. The siloxane resin composition for forming a cured film according to claim 14, wherein the (b) organic salt is an organic salt composed of an organic acid having a structure represented by any one of general formulae (1) to (3) and an amine: 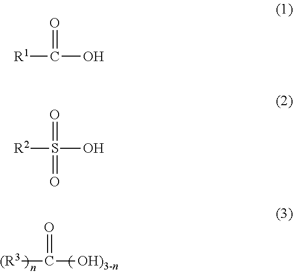
wherein, in general formulae (1) and (2), R¹ to R² each independently represent a monovalent organic group having 1 to 30 carbon atoms or a divalent organic group having 1 to 30 carbon atoms, and examples of the monovalent organic group include a substituted or unsubstituted linear or branched alkyl group, a substituted or unsubstituted cyclic alkyl group, a substituted or unsubstituted aryl group, and a perfluoroalkyl group, and examples of the divalent organic group include a substituted or unsubstituted alkylene group, a substituted or unsubstituted alkenylene group, and a substituted or unsubstituted phenylene group,
in general formula (3), n represents 0, 1, or 2, when n is 1, R³ in general formula (3) represents a monovalent organic group having 1 to 30 carbon atoms or a divalent organic group having 1 to 30 carbon atoms, and when n is 2, R³ in general formula (3) may be the same or different and represents hydrogen, a monovalent organic group having 1 to 30 carbon atoms, or a divalent organic group having 1 to 30 carbon atoms.

17. The siloxane resin composition for forming a cured film according to claim 16, wherein the amine is a heterocyclic amine or an aromatic amine.

18. The siloxane resin composition for forming a cured film according to claim 16, wherein the organic acid having a structure represented by any one of general formulae (1) to (3) is an organic acid selected from the group consisting of methanesulfonic acid, ethanesulfonic acid, propanesulfonic acid, benzenesulfonic acid, p-toluenesulfonic acid, xylenesulfonic acid, trifluoromethanesulfonic acid, trifluoroethanesulfonic acid, trifluoropropanesulfonic acid, and trifluoroacetic acid.

19. The siloxane resin composition for forming a cured film according to claim 17, wherein the heterocyclic amine or the aromatic amine is an amine selected from the group consisting of pyridine, 2,4-dimethylpyridine, 2,6-dimethylpyridine, 3,5-dimethylpyridine, 2,4,6-trimethylpyridine, and aniline.

20. The siloxane resin composition for forming a cured film according to claim 14, wherein the (d) photosensitizer is a photopolymerization initiator, and the siloxane resin composition further comprises a photopolymerizable compound.

21. The siloxane resin composition for forming a cured film according to claim 14, wherein the (a) polysiloxane has an aromatic group and/or a substituted aromatic group in a side chain group, and a content of each of benzene, toluene, xylene, aniline, styrene, and naphthalene in the resin composition is less than 1 ppm.

22. The siloxane resin composition for forming a cured film according to claim 14, wherein the cured film is a permanent film.

23. A cured film obtained by curing the resin composition for forming a cured film according to claim 14.

24. The cured film according to claim 23, wherein an atomicity ratio of N to Si as measured by a scanning electron microscope (SEM-EDX) is 0.005 or more and 0.200 or less, and an atomicity ratio of at least one atom selected from S, P, and F to Si is 0.005 or more and 0.200 or less.
